(19) United States
(12) Patent Application Publication
(10) Pub. No.: US 2025/0366347 A1
(43) Pub. Date: Nov. 27, 2025

(54) DISPLAY APPARATUS, APPARATUS FOR MANUFACTURING DISPLAY APPARATUS AND ELECTRONIC APPARATUS

(71) Applicant: Samsung Display Co., Ltd., Yongin-si (KR)

(72) Inventors: Shinya Onoue, Yongin-si (KR); Jaeyoung Sim, Yongin-si (KR); Soyeon Joo, Yongin-si (KR); Minhee Park, Yongin-si (KR); Jongdeok Park, Yongin-si (KR)

(21) Appl. No.: 19/213,704

(22) Filed: May 20, 2025

(30) Foreign Application Priority Data
May 22, 2024 (KR) 10-2024-0066737

(51) Int. Cl. H10K 59/80; H10K 59/12; H10K 59/131; H10K 77/10; H10K 102/00

(52) U.S. Cl. CPC H10K 59/871; H10K 59/1201; H10K 59/131; H10K 77/111; H10K 2102/311

(57) ABSTRACT

A display apparatus includes a display panel, the display panel including: a substrate including a display area, a pad area, and a bending area, wherein the display area and the pad area have a width in a first direction and a length in a second direction, and the bending area connects the display area to the pad area in the second direction and bends such that the display area faces the pad area; a first protective layer inside the bending area of the substrate; and a second protective layer on at least a portion of the edge of the substrate and outside the bending area, wherein the second protective layer includes a groove concave toward an inner surface from an outer surface of the second protective layer.

### CROSS-REFERENCE TO RELATED APPLICATION

The present application claims priority to and the benefit of Korean Patent Application No. 10-2024-0066737, filed on May 22, 2024, in the Korean Intellectual Property Office, the entire disclosure of which is incorporated herein by reference.

### BACKGROUND

### 1. Field

Aspects of some embodiments relate to a display apparatus, an apparatus for manufacturing the display apparatus and an electronic apparatus.

### 2. Description of the Related Art

Mobile electronic apparatuses are widely used. In addition to miniaturized electronic apparatuses such as mobile phones, tablet personal computers (PCs) have recently become widely used as mobile electronic apparatuses.

To provide various functions, for example, to provide a user with visual information, that is, images, the mobile electronic apparatuses include a display apparatus. Recently, a proportion of a display apparatus in an electronic apparatus is gradually increasing, and a structure that allows the display apparatus to be bent at a preset angle with respect to a flat state is also under development.

The above information disclosed in this Background section is only for enhancement of understanding of the background and therefore the information discussed in this Background section does not necessarily constitute prior art.

### SUMMARY

Aspects of some embodiments relate to a display apparatus, an apparatus for manufacturing the display apparatus and an electronic apparatus, and for example, to a display apparatus configured to prevent or reduce defects in a resin layer on a display panel, an apparatus for manufacturing the display apparatus and an electronic apparatus.

According to some embodiments, a display apparatus includes a display panel. The display panel may be inserted into a housing. Impacts may be applied to the edge of the display panel due to contact between the display panel and the housing, causing destruction of the display panel.

Aspects of some embodiments include a display apparatus configured to not only prevent or reduce destruction of a display panel received in a housing but also protect a bending portion of the display panel, and an apparatus for manufacturing the display apparatus.

However, such characteristics are just examples, and embodiments according to the present disclosure are not limited thereto.

Additional aspects will be set forth in part in the description which follows and, in part, will be apparent from the description, or may be learned by practice of the presented embodiments of the disclosure.

According to some embodiments, a display apparatus includes a display panel, wherein the display panel includes a substrate including a display area, a pad area, and a bending area, wherein the display area and the pad area have a width in a first direction and a length in a second direction, and the bending area connects the display area to the pad area in the second direction and bends such that the display area faces the pad area, a first protective layer arranged inside the bending area of the substrate, and a second protective layer arranged on at least a portion of the edge of the substrate and outside the bending area, wherein the second protective layer includes a groove concave toward an inner surface from an outer surface of the second protective layer.

According to some embodiments, the groove may be located within a width in the first direction of the bending area.

According to some embodiments, the groove may be located between one side end of the width in the first direction of the bending area and a center of the width.

According to some embodiments, an inner surface of the groove may be spaced apart in a thickness direction of the second protective layer from the bending area and an outer surface of the pad area.

According to some embodiments, a depth of the groove may be in a range of 70% to 85% of a thickness of the second protective layer.

A cross-section of the groove viewed in a first direction may have a ‘¬’ shape.

According to some embodiments, in a view from the second direction, a cross-section of the groove may be concave and gets increasingly deeper toward a center thereof.

According to some embodiments, in a view from the second direction, the cross-section of the groove may include a first inner surface and a second inner surface, the first inner surface being on one side in the first direction from the center of the groove and inclined, and the second inner surface being on the other side in the first direction and inclined.

According to some embodiments, a slope of the first inner surface may be greater than a slope of the second inner surface.

According to some embodiments, a slope angle of the first inner surface may be in a range of 50° to 70°.

According to some embodiments, the first protective layer and the second protective layer may include a photocurable resin.

According to some embodiments, an apparatus for manufacturing a display apparatus includes a first jig, a second jig on which a display panel is seated, the second jig facing the first jig, and a mold between the first jig and the second jig, selectively coupled to the first jig, and forming a space in an edge portion of the display panel in cooperation with the second jig, wherein a resin is injected into the space, wherein the display panel includes a bending area arranged in a portion of the edge portion to bend, and the mold includes a first mold portion including a first space in which the bending area is received and which is an inner space of the bending area, and a second space which is an outer space of the bending area, wherein the first mold portion includes a blocking portion protruding from an inner surface thereof toward the bending area.

According to some embodiments, in a rear view, the blocking portion may be arranged in a width of the bending area.

According to some embodiments, in a rear view, the blocking portion may be located between one side end of a width of the bending area and a center of the width.

According to some embodiments, a protrusion length of the blocking portion from the inner surface of the first mold portion may be in a range of 70% to 85% of a length from the inner surface of the first mold portion to an outer surface of the bending area.

According to some embodiments, in a view from a width direction of the bending area, a cross-section of the blocking portion may have a ‘¬’ shape.

According to some embodiments, in a view from a length direction of the bending area, a cross-section of the blocking portion may protrude more toward a center thereof.

According to some embodiments, in a view from a length direction of the bending area, a cross-section of the blocking portion may include a first inclined surface arranged on one side of a center of the blocking portion and inclined, and a second inclined surface arranged on the other side and inclined.

According to some embodiments, a slope of the first inclined surface may be greater than a slope of the second inclined surface.

According to some embodiments, the first mold portion may further include an injector through which resin is injected into the first space, and the first inclined surface may be closer to the injector than the second inclined surface.

According to some embodiments, an electronic apparatus comprises a display panel and a bracket supporting the display panel, wherein the display panel includes a substrate including a display area, a pad area, and a bending area, wherein the display area and the pad area have a width in a first direction and a length in a second direction, and the bending area connects the display area to the pad area in the second direction and bends such that the display area faces the pad area, a first protective layer arranged inside the bending area of the substrate, and a second protective layer arranged on at least a portion of the edge of the substrate and outside the bending area, wherein the second protective layer includes a groove concave toward an inner surface from an outer surface of the second protective layer.

According to some embodiments, the electronic apparatus further comprises a main circuit board, wherein a main circuit board comprises at least one of a main processor, a camera apparatus and a main connector.

These and/or other aspects will become more apparent and more readily appreciated from the following detailed description of the embodiments, the accompanying drawings, and claims.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic perspective view of an electronic apparatus according to some embodiments;

FIG. 2 is a schematic exploded perspective view of the electronic apparatus shown in FIG. 1;

FIG. 3 is a schematic plan view of a display panel shown in FIG. 2;

FIG. 4 is a schematic rear view of the display panel shown in FIG. 2;

FIG. 5 is a cross-sectional view of the display panel shown in FIG. 3, taken along the line A-A′;

FIG. 6 is an enlarged cross-sectional view of a region B shown in FIG. 5;

FIG. 7 is a cross-sectional view of the display panel, taken along the line C-C′ of FIG. 4;

FIG. 8 is a cross-sectional view of the display panel, taken along the line ‘D-D’ of FIG. 4;

FIG. 9 is a schematic cross-sectional view of a display panel according to some embodiments, taken along the line E-E′ of FIG. 3;

FIGS. 10 and 11 are schematic circuit diagrams of a circuit of the display panel shown in FIG. 9;

FIG. 12 is a schematic perspective view of an apparatus for manufacturing a display apparatus according to some embodiments;

FIG. 13 is a schematic cross-sectional view of the apparatus for manufacturing a display apparatus shown in FIG. 12;

FIGS. 14 to 17 are schematic cross-sectional views showing an apparatus and method of manufacturing a display apparatus, according to some embodiments;

FIG. 18 is a schematic cross-sectional view of an apparatus for manufacturing a display apparatus according to some embodiments, taken along the line F-F′ of FIG. 14;

FIG. 19 is a schematic cross-sectional view of an apparatus for manufacturing a display apparatus according to some embodiments, taken along the line G-G′ of FIG. 14; and

FIG. 20 is a schematic cross-sectional view of an apparatus for manufacturing a display apparatus according to some embodiments, and is similar to FIG. 14.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously (or concurrently) performed substantially and performed in the opposite order.

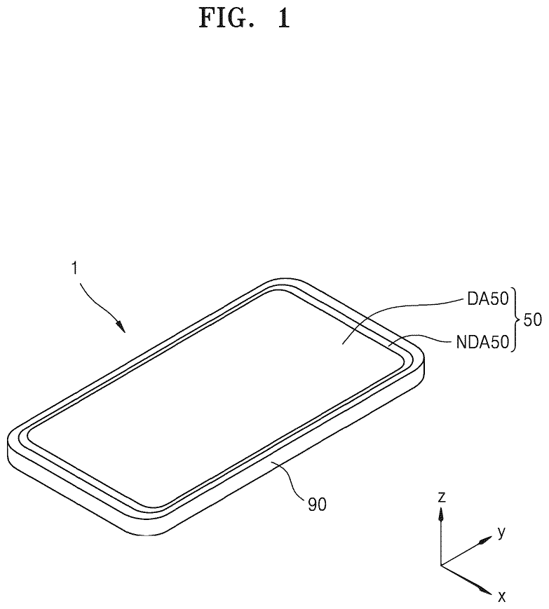

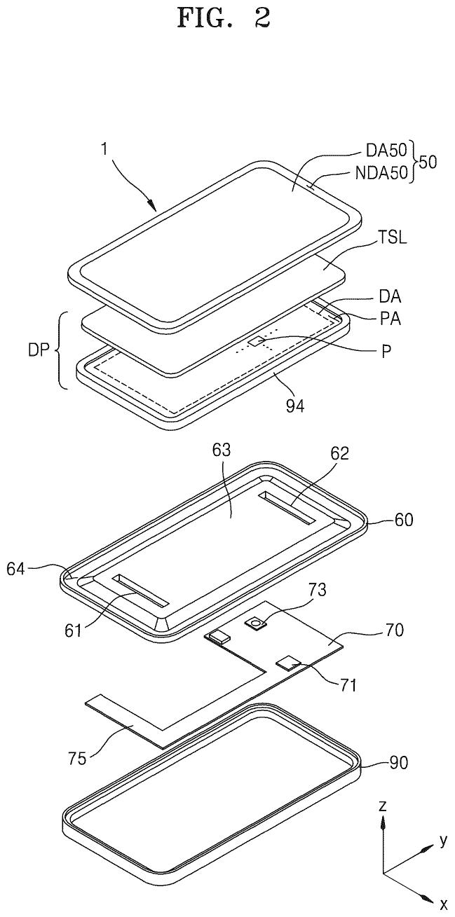

FIG. 1 is a schematic perspective view of an electronic apparatus 1 according to some embodiments. FIG. 2 is a schematic exploded perspective view of the electronic apparatus 1 shown in FIG. 1.

Referring to FIGS. 1 and 2, the display apparatus 1 may include an apparatus for displaying moving images (e.g., video images) or still images (e.g., static images) and may be used as a display screen of various products including televisions, notebook computers, monitors, advertisement boards, Internet of things (IoTs) apparatuses as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus 1 may be used in wearable devices including smartwatches, watchphones, glasses-type displays, and head-mounted displays (HMDs). In addition, according to some embodiments, the display apparatus 1 may be used as a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

The electronic apparatus may include the display apparatus 1. The display apparatus 1 may include a display panel DP, a display circuit board 51, a cover member 50, a bracket 60, a main circuit board 70, and a lower cover 90.

The cover member 50 may be located on the display panel DP. According to some embodiments, the cover member 50 may cover the upper portion of the display panel DP. Accordingly, the cover member 50 may protect the upper surface of the display panel DP.

According to some embodiments, the cover member 50 may include a transmissive cover portion DA50 and a light-blocking cover portion NDA50, wherein the transmissive cover portion DA50 corresponds to the display panel DP, and the light-blocking cover portion NDA50 corresponds to a region other than the display panel DP. The light-blocking cover portion NDA50 may include an opaque material that blocks light. The light-blocking cover portion NDA50 may include a pattern that may be viewed to a user while images are not displayed.

The display panel DP may be located under the cover member 50. The display panel DP may overlap the transmissive cover portion DA50 of the cover member 50.

According to some embodiments, the cover member 50 may include a cover window and a protective member. According to some embodiments, the cover window may include a transparent or translucent material. In this case, the cover window may include glass, synthetic resin of a transparent material, and the like. The cover window may include at least one layer.

According to some embodiments, the protective member may be located on the upper surface of the cover window to prevent or reduce scratches and the like from occurring on the cover window. According to some embodiments, an opaque layer 50-1 may be located on at least one of the cover window or a portion of the protective member. According to some embodiments, the opaque layer 50-1 may be located on the edge of the cover window or the edge of the protective member. The opaque layer 50-1 may be configured to block light and located on the light-blocking cover portion NDA50 of the cover member 50.

The display panel DP may include a display area DA in which images are displayed, and a peripheral area PA around the display area DA. A sub-pixels P each including a display element may be arranged in the display area DA. In this case, the sub-pixel P may be provided as a plurality of sub-pixels, and the plurality of sub-pixels P may be arranged to be spaced apart from each other. Some of the plurality of sub-pixels P, others of the plurality of sub-pixels P, and still others of the plurality of sub-pixels P may be configured to emit light of different colors. The display apparatus 1 may be configured to display images using light emitted from the sub-pixels P arranged in the display area DA, and the peripheral area PA may be a region in which the sub-pixels P are not arranged.

The display panel DP may be configured to display (output) information processed by the display apparatus 1. As an example, the display panel DP may display execution screen information of an application driven in the display apparatus 1, or user interface (UI) and graphic user interface (GUI) information corresponding to the execution screen information. The display panel DP may include a display layer and a touch sensor layer TSL, wherein the display layer displays images, and the touch sensor layer TSL senses a user's touch input. Accordingly, the display panel DP may serve as one of input devices that provide an input interface between the display apparatus 1 and a user, and simultaneously (or concurrently), serve as one of output devices that provide an output interface between the display apparatus 1 and a user.

Hereinafter, although an organic light-emitting display apparatus is described as an example of the display apparatus 1 according to some embodiments, the display apparatus 1 is not limited thereto. According to some embodiments, the display apparatus 1 according to some embodiments may be an inorganic light-emitting display apparatus or a quantum-dot light-emitting display apparatus. As an example, an emission layer of a display element provided to the display apparatus 1 may include an organic material, an inorganic material, quantum dots, an organic material and quantum dots, or an inorganic material and quantum dots.

According to some embodiments, the display panel DP may be a flexible display panel which has flexibility and thus may be capable of being relatively easily bendable, foldable, or rollable without damaging the display panel DP. As an example, the display panel DP may include a foldable display panel that is foldable and unfoldable, a curved display panel that has a curved display surface, a bended display panel in which a region except a display surface is bent, a rollable display panel that is rollable and unrollable, and a stretchable display panel that is stretchable without damaging the display panel DP. According to some embodiments, the display panel DP may be a rigid display panel that has rigidity and thus does not easily bend.

The bracket 60 for supporting the display panel DP may be located under the display panel DP. The bracket 60 may include plastic, metal, or both plastic and metal. In this case, the bracket 60 may include a connector hole 61 through which a connector passes. In addition, the bracket 60 may include a camera hole 62 into which a camera apparatus 73 is inserted.

A receiving space in which a protective layer 93 is received may be located in the bracket 60. In addition, the bracket 60 may include a supporter 63 protruding toward the display panel DP to support the backside of the display panel DP. In this case, the supporter 63 may be in close contact with the rear surface of the display panel DP.

The main circuit board 70 may be provided separately from the display circuit board 51 or may be provided integrally with the display circuit board 51. In this case, in the case where the main circuit board 70 and the display circuit board 51 are separately provided to be distinct from each other, the main circuit board 70 and the display circuit board 51 may be connected to each other with a cable or the like. Hereinafter, for convenience of description, the case where the main circuit board 70 is provided separately from the display circuit board 51 is mainly described in detail.

The main circuit board 70 may include a main processor 71, the camera apparatus 73, a main connector 75, and components. The main processor 71 may include an integrated circuit. The camera apparatus 73 may be located on both the upper surface and the lower surface of the main circuit board 70, and the main processor 71 and the main connector 75 may each be located on one of the upper surface and the lower surface of the main circuit board 70.

The main processor 71 may be configured to control all functions of the display apparatus 1. As an example, the main processor 71 may be configured to output digital video data to a display driver 52 through the display circuit board 51 such that the display panel DP displays images. In addition, the main processor 71 may be configured to receive sensed data from the touch sensor driver 53. The main processor 71 may determine whether a user directly touches the touchscreen according to sensed data, and execute an operation corresponding to a user's direct touch or proximity touch. As an example, the main processor 71 may analyze sensed data and calculate a user's touch coordinates, and then execute an application indicated by an icon the user touches, or perform an operation. The main processor 71 may be an application processor including an integrated circuit, a central processing unit, or a system chip.

The camera apparatus 73 processes image frames such as still images or moving images obtained by an image sensor in a camera mode, and may output the image frames to the main processor 71. The camera apparatus 73 may include at least one of a camera sensor (e.g., a charge-coupled device (CCD), a complementary metal oxide semiconductor (CMOS), and the like), a photo sensor (or an image sensor), or a laser sensor. The camera apparatus 73 may be connected to an image sensor among components overlapping a component area and may process images input to the image sensor.

A cable passing through a connector hole 61 of the bracket 60 may be connected to the main connector 75, and thus, the main circuit board 70 may be electrically connected to the display circuit board 51.

In addition to the main processor 71, the camera apparatus 73, and the main connector 75, the main circuit board 70 may further include at least one of wireless communication parts, at least one of input units, at least one of sensor parts, at least one of output units, at least one of interface parts, a memory, and/or a power supply part.

The wireless communication part may include at least one of a broadcasting receiving module, a mobile communication module, a wireless Internet module, a short distance communication module, or a location information module.

The broadcasting receiving module may be configured to receive broadcasting signals and/or broadcasting-related information from an external broadcasting management server through a broadcasting channel. The broadcasting channel may include satellite channels, groundwave channels.

The mobile communication module may be configured to transmit/receive radio signals to/from at least one of a base station, an external terminal, or a server on a mobile communication network established according to technology standards for mobile communication or communication schemes (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and the like). Wireless signals may include voice call signals, image communication call signals, or various types of data corresponding to text/multimedia message transmission/reception.

The wireless Internet module may denote a module for wireless Internet access. The wireless Internet module may be configured to transmit/receive radio signals on a communication network according to wireless Internet technologies. Examples of wireless Internet technologies include wireless local area network (WLAN), wireless-fidelity (Wi-Fi), Wi-Fi Direct, and digital living network alliance (DLNA).

The short distance communication module is for short range communication, and may support short distance communication by using at least one of Bluetooth™, Radio Frequency Identification (RFID), Infrared Data Association; IrDA (IrDA), Ultra Wideband (UWB), ZigBee, Near Field Communication (NFC), Wi-Fi, Wi-Fi Direct, or Wireless Universal Serial Bus (Wireless USB) technologies. The short distance communication module may support wireless communication between the display apparatus 1 and a wireless communication system, between the display apparatus 1 and another the electronic apparatus, or between the display apparatus 1 and a network in which another electronic apparatus (or an external server) is located, through a short distance wireless area network. The short distance wireless area network may be a wireless personal area network. The other electronic apparatus may be a wearable device that may exchange data, or operate with the display apparatus 1.

The position information module is a module for obtaining the position (or the current position) of the display apparatus 1. Representative examples of the position information module 525 include a Global Positioning System (GPS) module or a Wi-Fi module. As an example, when the GPS module is utilized, the display apparatus 1 may obtain the position of the display apparatus 1 by using signals sent by GPS satellites. In addition, the display apparatus 1 may obtain the position of the display apparatus 1 based on information of a wireless access point (AP) that transmits/receives radio signals to/from the Wi-Fi module by using the Wi-Fi module. The position information module is a module for obtaining the position (or the current position) of the display apparatus 1. The position information module is not limited to a module for directly calculating or obtaining the position of the display apparatus 1.

The input unit may include an image input unit such as the camera apparatus for inputting image signals, a sound input unit such as a microphone for inputting sound signals, and the input unit for receiving information from a user.

The camera apparatus processes image frames such as still images or moving images obtained by an image sensor in an image communication mode or a photographing mode. The processed image frames may be displayed on the display panel DP or stored in the memory.

The microphone processes external sound signals as electrical voice data. The processed voice data may be variously utilized according to a function (or an application in execution) being performed in the display apparatus 1. Various noise cancelling algorithms may be implemented in the microphone, wherein the various noise cancelling algorithms cancel noises occurring during a process of receiving external sound signals.

The main processor 71 may control an operation of the display apparatus 1 to correspond to information input through the input unit. The input unit may include a mechanical input means such as buttons, a dome switch, a jog wheel, a jog switch, and the like, or a touch input means located on the lower surface or the lateral surface of the display apparatus 1. The touch input means may include the touch sensor layer of the display panel DP.

The sensor part may include at least one sensor that senses at least one of information inside the display apparatus 1, peripheral environmental information surrounding the display apparatus 1, or user information, and generates sensing signals corresponding thereto. The main processor may control driving or an operation of the display apparatus 1 based on the sensing signals, or perform data processing, a function, or an operation related to an application installed in the display apparatus 1. The sensor part may include at least one of a proximity sensor, an illumination sensor, an acceleration sensor, a magnetic sensor, a G-sensor, a gyroscope sensor, a motion sensor, an RGB sensor, an infrared sensor, a finger scan sensor, an ultrasonic sensor, an optical sensor, a battery gauge, an environment sensor (e.g., a barometer, a hygrometer, a thermometer, a radiation detection sensor, a heat detection sensor, a gas detection sensor, and the like), or a chemical sensor (e.g., an electronic nose, a healthcare sensor, a biometric sensor, and/or the like).

A proximity sensor denotes a sensor that detects whether there is an object approaching a preset detection surface or an object existing in the neighborhood by using electromagnetic force, an infrared ray, or the like without a mechanical contact. Examples of the proximity sensor include a transmissive photo-electric sensor, a direct reflective photo-electric sensor, a mirror reflective photo-electric sensor, a high-frequency oscillation type proximity sensor, a capacitance type proximity sensor, a magnetic proximity sensor, and an infrared proximity sensor. The proximity sensor may sense not only a proximity touch, but also a proximity touch pattern such as a proximity touch distance, a proximity touch direction, a proximity touch velocity, a proximity touch time, a proximity touch position, and a proximity touch movement state. The main processor may process data (or information) corresponding to a proximity touch operation and a proximity touch pattern sensed by the proximity sensor, and control the display panel DP to display visual information corresponding to the processed data.

The ultrasonic sensor may recognize the position information of an object by using ultrasonic waves. The main processor may calculate the position of an object by using information sensed by an optical sensor and a plurality of ultrasonic sensors. Because the velocity of light is different from the velocity of ultrasonic waves, the position of an object may be calculated by using a time during which light reaches a light sensor and a time during which ultrasonic waves reach the ultrasonic sensor.

The output unit may be configured to generate an output related to vision, hearing, or tactile sensation, and may include at least one of a sound output unit, a haptic module, or a light output unit.

The sound output unit may output sound data received by the wireless communication unit or stored in the memory in a call reception mode, a communication mode or recoding mode, a voice recognition mode, a broadcasting reception mode, and the like. The sound output unit may output sound signals related to a function (e.g., a call signal reception tone, a message reception tone, and the like) performed by the display apparatus 1. The sound output unit may include a receiver and a speaker. At least one of the receiver or the speaker may be a sound generator that is attached under the display panel DP and vibrates the display panel DP to output sounds. The sound generator may be a piezoelectric element or a piezoelectric actuator that contacts and expands according to electrical signals, or an exciter that generates magnetic force by using a voice coil to vibrate the display panel DP.

The haptic module generates various haptic effects that may be felt by a user. The haptic module may provide vibrations to a user as a haptic effect. The intensity, the pattern, and the like of vibrations generated by the haptic module may be controlled by a user's selection or setting of the main processor. As an example, the haptic module may synthesize different vibrations to output the same, or sequentially output the different vibrations. The haptic module may generate various tactile effects such as effects due to the arrangement of pins that move perpendicular to the surface of a skin in contact, the blowing force or suction power of air through a nozzle or a suction port, sweep to the skin surface, an electrode contact, stimulus of electrostatic force, and effects due to reproduction of cool and warm feeling using elements that may absorb heat or generate heat, as well as vibrations. The haptic module may not only transfer a tactile effect through a direct contact but implement a tactile effect such that a user may feel the tactile effect through a muscle sense in fingers or arms.

The light output unit outputs signals for informing occurrence of an event by using light of a light source. Examples of an event generated in the display apparatus 1 may include message reception, signal reception, a missed call, alarm, schedule notification, e-mail reception, information reception through an application, and the like. Signals output by the light output unit are implemented when the display apparatus 1 emits light of a single color or a plurality of colors to the front surface or the rear surface. The signal output may end when the display apparatus 1 detects that a user confirms an event.

The interface part serves as a path with various kinds of external apparatuses connected to the display apparatus 1. The interface part may include at least one of a wired/wireless headset port, an external charger port, a wired/wireless data port, a memory card part, a port for connecting an apparatus having an identification module, an audio input/output (I/O) port, a video I/O port, or an earphone port. When an external apparatus is connected to the interface part, the display apparatus 1 may perform an appropriate control related to the external apparatus connected.

The memory stores data that support various functions of the display apparatus 1. The memory may store a plurality of application programs driven in the display apparatus 1, data for operations of the display apparatus 1, and commands. At least some of the plurality of application programs may be downloaded from an external server through wireless communication. The memory may store an application program for operations of the main processor, and temporarily store data input/output, for example, data such as a phone book, messages, still images, moving images, and the like. In addition, the memory may be configured to store haptic data for vibration of various patterns provided to the haptic module, and sound data related to various sounds provided to the sound output unit. The memory may include at least one type of storing medium among a flash memory type, a hard disk type, a solid state disk (SSD) type, a silicon disk drive (SDD) type, a multimedia card micro type, a card type memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply part receives an external power and an internal power under control of the main processor, and may supply power to respective elements included in the display apparatus 1. The power supply part may include a battery. In addition, the power supply part includes a connection port. The connection port may be configured as an example of the interface part to which an external charger is electrically connected, wherein the external charger supplies power to charge the battery. Alternatively, the power supply part may be configured to charge the battery wirelessly without using the connection port. The battery may receive power from an external wireless power transfer apparatus by using at least one of inductive coupling or magnetic resonance coupling, wherein the inductive coupling is based on magnetic induction, and the magnetic resonance coupling is based on electromagnetic resonance. The battery may be arranged in a third direction (a z direction) not to overlap the main circuit board. The battery may overlap a battery hole of the bracket 60.

The lower cover 90 may be located under the main circuit board 70 and the battery. The lower cover 90 may be fastened and fixed to the bracket 60. The lower cover 90 may form the lower appearance of the display apparatus 1. The lower cover 90 may include plastic, metal, or both plastic and metal.

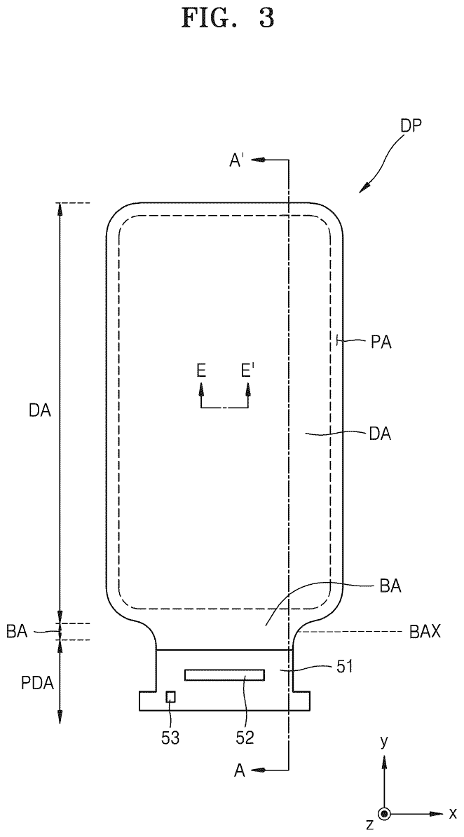

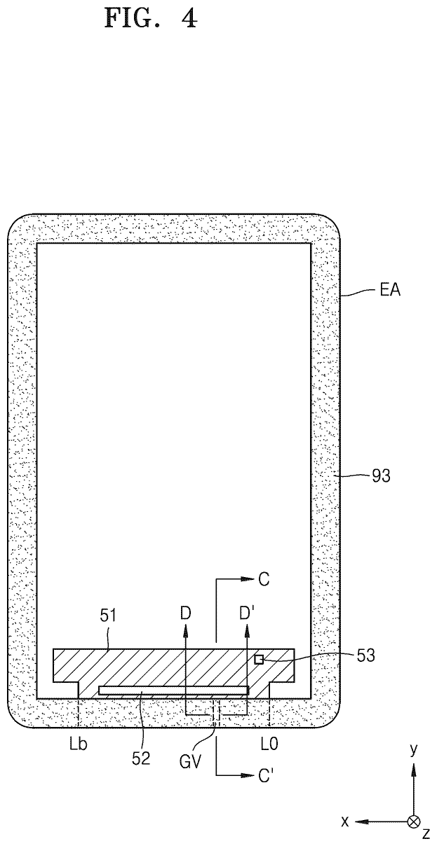

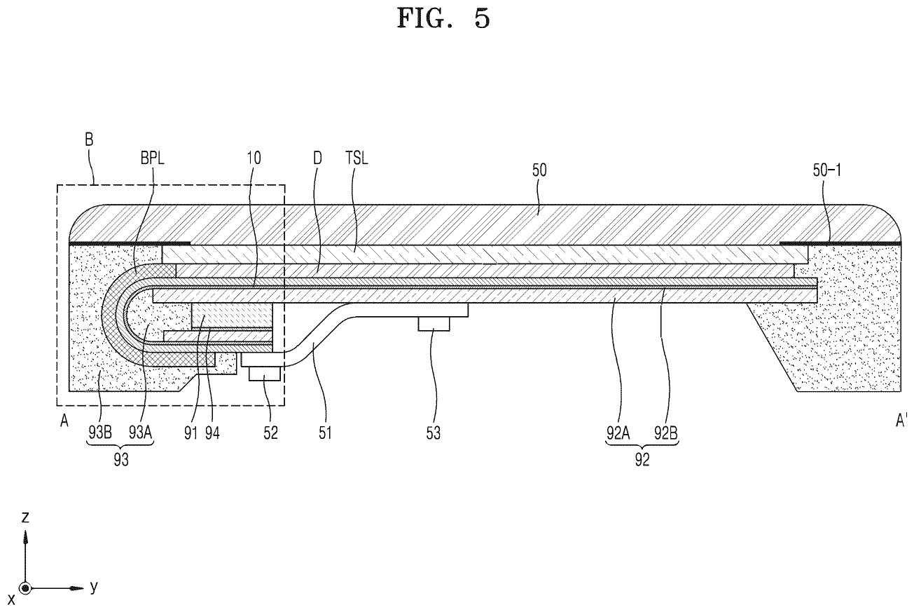

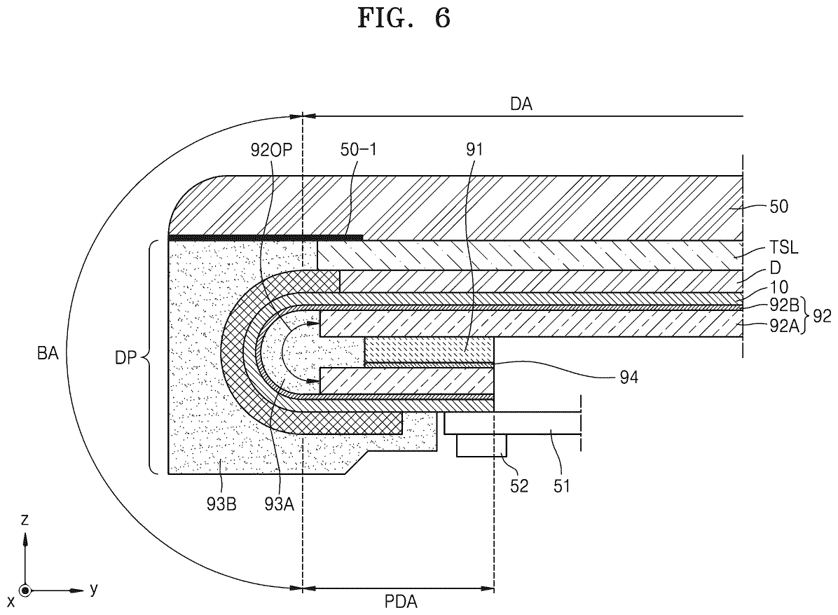

FIG. 3 is a schematic plan view of the display panel shown in FIG. 2. FIG. 4 is a schematic backside view of the display panel shown in FIG. 2. FIG. 5 is a cross-sectional view of the display panel shown in FIG. 3, taken along the line A-A′. FIG. 6 is an enlarged cross-sectional view of the region B shown in FIG. 5. For convenience of description, FIG. 3 omits the protective layer, and FIGS. 4 to 6 schematically show a shape in which at least a portion of the display panel shown in FIG. 3 bends.

Referring to FIGS. 3 to 6, the display panel DP may be a light-emitting display panel including a light-emitting element. As an example, the display panel DP may be an organic light-emitting display panel that uses an organic light-emitting diode that includes an organic emission layer, an ultra-miniature light-emitting diode display panel that uses a micro light-emitting diode, a quantum-dot light-emitting display panel that uses a quantum-dot light-emitting diode including a quantum-dot emission layer, or an inorganic light-emitting display panel that uses an inorganic light-emitting element including an inorganic semiconductor.

The display panel DP may be a flexible display panel which has flexibility and thus is easily bendable, foldable, or rollable. As an example, the display panel DP may include a foldable display panel that is foldable and unfoldable, a curved display panel that has a curved display surface, a bended display panel in which a region except a display surface is bent, a rollable display panel that is rollable and unrollable, and a stretchable display panel that is stretchable.

The display panel DP may be implemented transparent and be a transparent display panel such that an object or background located below the display panel DP is viewable from the upper surface of the display panel DP. Alternatively, the display panel DP may be a reflective display panel that may reflect an object or background over the upper surface of the display panel DP.

The display panel DP may include the display area DA in which images are displayed, and the peripheral area PA arranged to surround the display area DA. A separate driving circuit, a pad, and the like may be arranged in the peripheral area PA.

For example, the peripheral area PA may include a bending area BA and a pad area PDA, wherein the bending area BA bends around a bending axis BAX, and the pad area PDA is connected to the bending area BA, the display circuit board 51 being arranged in the pad area PDA. In the display panel DP, a portion of the substrate 10 may bend around the virtual bending axis BAX arranged in the bending area BA. That is, because the display panel DP bends in the bending area BA, the display area DA and the pad area PDA may be arranged to face each other. In this case, because the display area DA, the pad area PDA, and the bending area BA are formed in a ‘U’ shape, a space in which a first protective layer 93A is located may be formed. The first protective layer 93A may be located in an inner space of the bending area BA, and a second protective layer 93B may be arranged in an edge EA of the display panel DP and the outer surface of the bending area BA.

The display panel DP may include the substrate 10, a display layer D located on the substrate 10, the touch sensor layer TSL located on the display layer D, and a protective layer 93 arranged to surround the lateral surface of the substrate 10 and the display layer D. In this case, at least a portion of the substrate 10 may bend. The protective layer 93 may include the first protective layer 93A and the second protective layer 93B, wherein the first protective layer 93A is located inside the bending portion of the substrate 10, and the second protective layer 93B is located on at least a portion of the edge of the substrate 10 and the display layer D. The first protective layer 93A and the second protective layer 93B may be connected to each other. The first protective layer 93A may be located in a space formed by the display area DA, the pad area PDA, and the bending area BA. Hereinafter, for convenience of description, the case where the second protective layer 93B surrounds the entire edge of the substrate 10 is mainly described in more detail. In this case, the second protective layer 93B may be arranged to surround not only the edge of the substrate 10 but also the outer surface of a bending protective layer BPL.

In addition, according to some embodiments, the second protective layer 93B may include a groove GV (see FIG. 4). The groove GV may be located in a portion of the second protective layer 93B that surrounds one edge of the substrate 10 in which the bending area BA is arranged. That is, the groove GV may be located in a portion of the second protective layer 93B that surrounds the bending area BA. The groove GV may extend in a direction (e.g., the y direction) crossing a width direction (e.g., an x direction) of the bending area BA. According to some embodiments, the groove GV may be formed to be concave along the outer circumference of the bending area BA and the pad area PDA from the bending area BA toward the pad area PDA. The groove GV may have a concave shape like an approximately half ring. The groove GV may be formed according to the process of manufacturing the display apparatus. This is described below in detail.

The protective layer 93 may include a photocurable resin according to some embodiments. In this case, the photocurable resin may be cured when light is irradiated thereto. Particularly, the photocurable resin may be cured by light having a wavelength in the range with a peak top from 450 nm to 500 nm (or about 450 nm to about 500 nm). In this case, when the peak top of the wavelength of light is less than 450 nm, because the light cannot pass through the substrate 10, the first protective layer 93A and the second protective layer 93B may not be cured together. In addition, light with the peak top of the wavelength exceeding 500 nm is irradiated, because excessive heat is included, destruction of the display panel DP and the like may be caused by the heat.

The photocurable resin may include photoinitiator. In this case, the photocurable resin including the photoinitiator may include at least one of diphenyl (2,4,6-trimethylbenzoyldiphenyl phosphine oxide), ethyl(2,4,6-trimethylbenzoyl) phenylphosphinate), bis-acylphosphine oxides, bis(cyclopentadienyl)-bis(2,6-difluoro-3-(pyrrole)-1-yl)-phenyl) titanium (Bis(cyclopentadienyl)-bis[2,6-difluoro-3-(pyrrol-1-yl)-phenyl]titaninum), or camphoquinone (CQ).

The display panel DP may be located under the cover member 50. The display panel DP may include a protective film 92 and an adhesive member 94 located on the lower portion of the substrate 10. In this case, the protective film 92 may include a protective film base 92A and an adhesive layer 92B. The protective film base 92A may include polyethylene terephthalate (PET) or polyimide (PI). In addition, the adhesive layer 92B may include various adhesive materials. In this case, the adhesive layer 92B may be located on the entire surface of the substrate 10, and the protective film base 92A may be located on the adhesive layer 92B and then a portion of the protective film base 92A may be removed to form an opening 920P. According to some embodiments, a portion of the protective film base 92A and a portion of the adhesive layer 92B may be removed to form the opening 920P. In this case, there may not be both the protective film base 92A and the adhesive layer 92B in the opening 92OP.

In addition, the display panel DP may include a cushion layer 91 located between the protective film base 92A and the display paned DP. In this case, the cushion layer 91 may be located in a space in which the display area DA faces the pad area PDA. That is, the cushion layer 91 may be arranged to be in contact with a portion of the protective film base 92A in the display area DA and a portion of the protective film base 92A in the peripheral area PDA. The cushion layer 91 may be located in the space by which the display area DA is spaced apart from the pad area PDA after the substrate 10 and the like bend, to support the display panel DP and absorb impacts. The cushion layer 91 may include an elastic material. In this case, the display apparatus is not limited thereto, and the cushion layer 91 may be attached to the protective film base 92A before the bending.

The display panel DP may be connected to the display circuit board 51 using an anisotropic conductive film. The touch sensor driver 53 may be located on the display circuit board 51. According to some embodiments, the display driver 52 may be directly located on the substrate 10 of the display panel DP. According to some embodiments, the display driver 52 may be located on the display circuit board 51. Hereinafter, for convenience of description, the case where the display driver 52 is located on the display circuit board 51 is mainly described in more detail.

At least a portion of the substrate 10 of the display panel DP may bend. In this case, the bending protective layer BPL may be located on a bending portion, that is, the bending area BA of the substrate 10 to prevent or reduce cracks and the like of the substrate 10. The bending protective layer BPL may include polymer resin such as polyethyleneterephthalate (PET), polyimide (PI), and the like.

According to some embodiments, the display apparatus 1 may include a panel protective member located under the display panel DP.

The touch sensor layer TSL may be formed in a panel form or a film form. Alternatively, the touch sensor layer TSL may be integrally formed with the display panel DP. As an example, in the case where the touch sensor layer TSL is formed in a film form, the touch sensor layer TSL may be integrally formed with a thin-film encapsulation layer 30 (see FIG. 6) for encapsulating the display panel DP.

According to some embodiments, the touch sensor layer TSL may have electrodes arranged in a pattern on the display panel DP. In this case, wirings may be located on the thin-film encapsulation layer 30 to cross each other, and a change in capacitance that varies depending on a user's touch may be measured at the intersection point. The touch sensor layer TSL may be connected to the display circuit board 51.

The touch sensor driver 53 may be configured to apply touch driving signals to the touch sensor layer TSL, sense first sensing signals sensed from the touch sensor layer TSL, and calculate a user's touch position by analyzing the first sensing signals. In addition, the touch sensor driver 53 may be configured to apply touch driving signals to a sensing part, sense second sensing signals sensed from the sensing part, and calculate a touch position of a signal input unit by analyzing the second sensing signals.

According to some embodiments, a functional layer may be located on the touch sensor layer TSL. The functional layer may include an anti-reflection layer. The anti-reflection layer may reduce reflectivity of light (external light) incident through the display apparatus 1 from the outside.

According to some embodiments, the anti-reflection layer may include a polarizing film. The polarizing film may include a linear polarizing plate and a phase-retarding film such as a A/4 (quarter-wave) plate. The phase-retarding film may be located on the touch sensor layer, and the linear polarizing film may be located on the phase-retarding film.

According to some embodiments, the anti-reflection layer may include a filter layer including a black matrix and color filters. The color filters may be arranged by taking into account colors of light emitted respectively from the sub-pixels of the display panel DP. As an example, the filter layer may include a red, blue, or green color filter. In this case, the filter layer may be located on the touch sensor layer TSL of the display panel DP without a separate adhesive layer.

According to some embodiments, the anti-reflection layer may include a destructive interference structure. The destructive interference structure may include a first reflection layer and a second reflection layer respectively located on different layers. First-reflected light and second-reflected light respectively reflected by the first reflection layer and the second reflection layer may destructively interfere and thus the reflectivity of external light may be reduced.

According to some embodiments, the functional layer may further include an impact absorption layer. In this case, the impact absorption layer may be configured to protect a structure such as the display panel and the like in the lower portion from external impacts. According to some embodiments, the impact absorption layer may include a polymer film. The polymer film include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC).

According to some embodiments, the functional layer may further include an anti-reflection layer and an impact absorption layer. In this case, the anti-reflection layer and the impact absorption layer may be sequentially stacked on the display panel DP or the touch sensor layer TSL.

The display circuit board 51 may be attached on one side of the display panel DP. For example, the display circuit board 51 may be attached on pads prepared on one side of the display panel DP using an isotropic conductive film. The display circuit board 51 may be connected to the main circuit board 70 through a display connector.

The display panel DP may include the display area DA and the pad area PDA each having a width in the first direction (e.g., the x direction) and a length in the second direction (e.g., the y direction) crossing the first direction. In this case, the display area DA and the pad area PDA may be arranged side-by-side in the second direction, and the bending area BA may be arranged between the display area DA and the pad area PDA to connect the display area DA and the pad area PDA. In addition, the bending area BA may bend such that the display area DA and the pad area PDA face each other. In this case, it would be understood that the bending area BA is connected to one of the edges of the display area DA.

The edge of the display area DA in which the bending area BA is arranged is mainly described. The first protective layer 93A may be located in the inner side of the bending area BA, that is, a space formed by the display area DA, the bending area BA, and the pad area PDA. The second protective layer 93B may be located outside the bending area BA to surround the bending area BA and also surround at least a portion of the pad area PDA. In addition, the first protective layer 93A and the second protective layer 93B may be connected to each other. That is, the first protective layer 93A and the second protective layer 93B are separated by being arranged inside and outside the bending area BA, but may be integrated with each other at an edge portion of the display panel DP where the bending area BA is not arranged. In other words, the protective layer 93 may be branched from the bending area BA and divided into the first protective layer 93A inside the bending area BA and the second protective layer 93B outside the bending area BA.

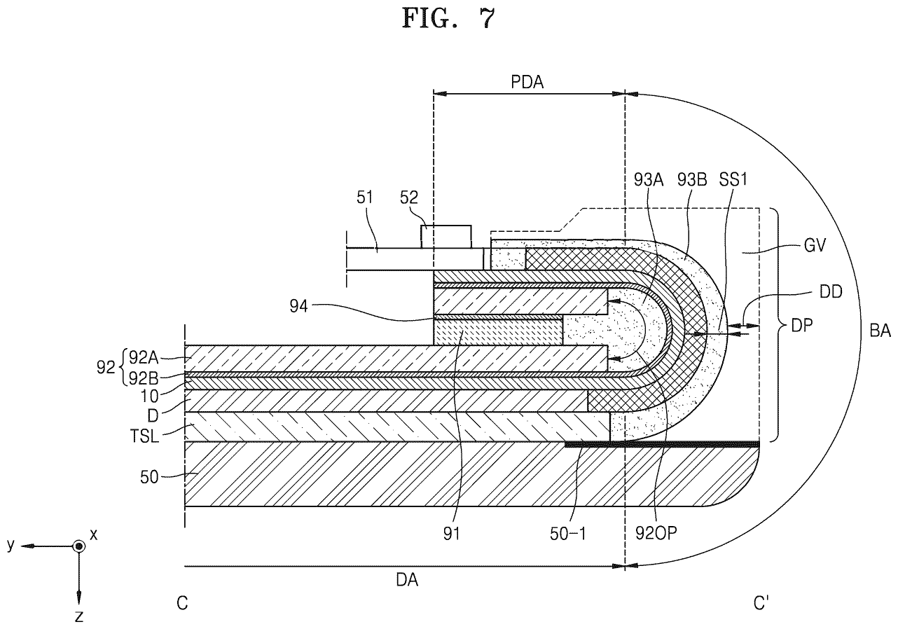

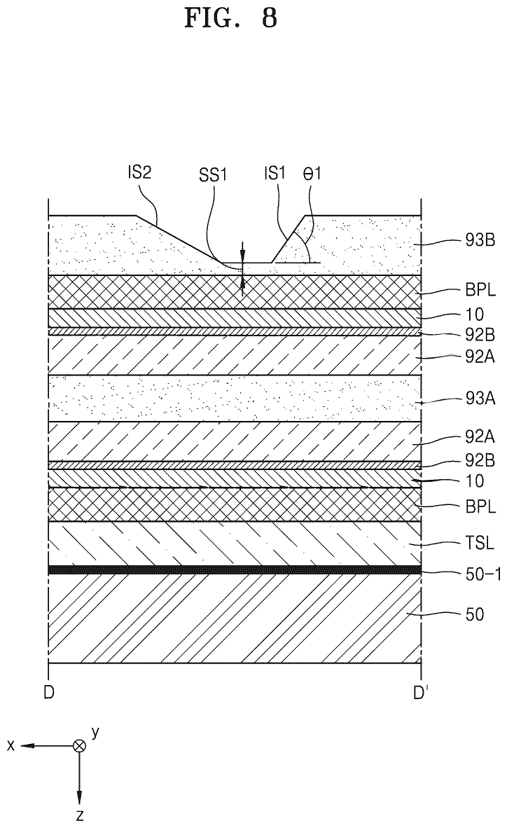

FIG. 7 is a cross-sectional view of the display panel, taken along the line C-C′ of FIG. 4. FIG. 8 is a cross-sectional view of the display panel, taken along the line D-D′ of FIG. 4.

Referring to FIGS. 7 and 8 additionally, according to some embodiments, the second protective layer 93B may include a groove GV. In the backside view of FIG. 4, the groove GV may be located within the width of the bending area BA, for example, within the length in the first direction of the bending area BA. According to some embodiments, the groove GV may be located between one end of the width of the bending area BA, for example, a first end, which is a right end in FIG. 4, and the center of the width of the bending area BA. In other words, when the location of the first end, which is the right end of the bending area BA, is defined as L0 and the location of the second end, which is the left end, is defined as Lb, the groove GV may be located between L0 and Lb. In addition, the groove GV may be located between L0 and 0.75 Lb, or located between L0 and 0.5 Lb.

The groove GV may have a shape that is concave from the outer surface toward the inner surface of the second protective layer 93B. In the backside view of FIG. 4, the groove GV may be arranged to overlap the bending area BA and a portion of the pad area PDA. In other words, the groove GV may be arranged outside the bending area BA and the pad area PDA. In this case, the inner surface of the groove GV may be spaced apart by a preset interval SS1 in a thickness direction of the second protective layer 93B from the outer surface of the bending area BA and the pad area PDA. According to some embodiments, a depth DD of the groove GV may be in a range of 70% to 85% (or about 70% to about 85%) of the thickness of the second protective layer 93B. That is, the depth DD of the groove GV may be in a range of 70% to 85% (or about 70% to about 85%) of a distance between the outer surface of the second protective layer 93B and the outer surface of the bending area BA.

In addition, referring to FIG. 7, when viewed in the first direction (e.g., the x direction), the cross-section of the groove GV may have a shape that is concave in an approximately ‘¬’ shape.

Referring to FIG. 8, when viewed in the second direction (e.g., the y direction), which is a lengthwise direction, the cross-section of the groove GV may be formed to be concave that becomes increasingly deeper toward the center of the groove GV. According to some embodiments, when viewed in the second direction, the cross-section of the groove GV may include a first inner surface IS1 and a second inner surface IS2, wherein the first inner surface IS1 is located on one side in the first direction (e.g., the x direction), which is the width direction, from the center of the groove GV and inclined, and the second inner surface IS2 is located on the other side in the first direction (e.g., the x direction) from the center of the groove GV and inclined. The first inner surface IS1 may be arranged on a side adjacent to the first end of the bending area BA, and the second inner surface IS2 may be arranged on a side adjacent to the second end of the bending area BA. According to some embodiments, the slope of the first inner surface IS1 may be greater than the slope of the second inner surface IS2. In this case, the slopes and the slope angles of the first inner surface IS1 and the second inner surface IS2 may denote angles inclined from the plane of the bending protective layer BPL. In addition, according to some embodiments, a slope angle θ1 of the first inner surface IS1 may be in a range of 50° to 70° (or about 50° to about 70°). Because the slope of the first inner surface IS1 is greater than the slope of the second inner surface IS2, the concave cross-section of the groove GV may be formed to be concave in approximately a half-streamline shape.

The groove GV may be formed in the process of manufacturing the display apparatus. This is described below in detail.

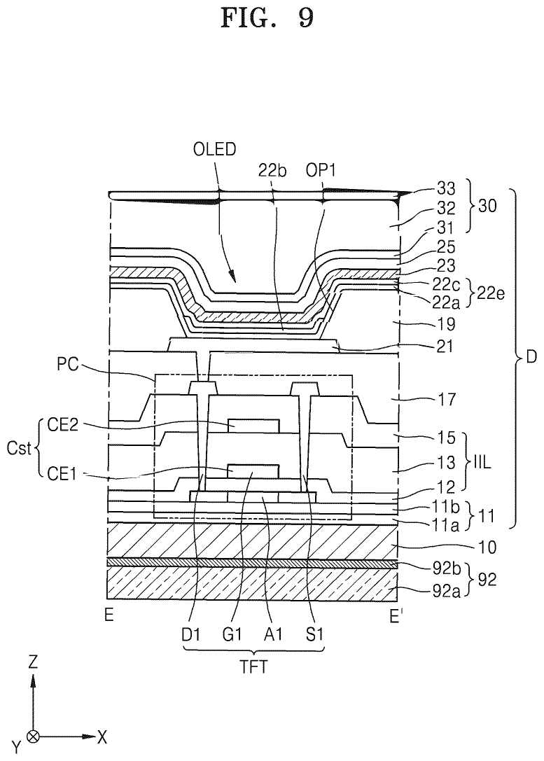

FIG. 9 is a schematic cross-sectional view of the display panel DP according to some embodiments, taken along the line E-E′ of FIG. 3.

Referring to FIG. 9, the display panel DP may include the substrate 10 and the display layer D. The display layer D may include a buffer layer 11, a circuit layer, a display element layer, and the thin-film encapsulation layer 30 that are stacked.

As described above, the substrate 10 may include an insulating material such as glass, quartz, a polymer resin or the like. The substrate 10 may be a flexible substrate that is bendable, foldable, and rollable.

The buffer layer 11 may be located on the substrate 10, may reduce or block penetration of foreign materials, moisture, or external air from below the substrate 10, and provide a flat surface on the substrate 10. The buffer layer 11 may include an inorganic material, an organic material, or an organic/inorganic composite material, and include a single layer or a multi-layer including an inorganic material and an organic material, the inorganic material including oxide or nitride. A barrier layer may be further located between the substrate 10 and the buffer layer 11, the barrier layer blocking penetration of external air. According to some embodiments, the buffer layer 11 may include silicon oxide (SiO₂) or silicon nitride (SiNₓ). The buffer layer 11 may include a first buffer layer 11a and a second buffer layer 11b that are stacked.

The circuit layer may be located on the buffer layer 11 and may include a pixel circuit PC, a first gate insulating layer 12, a second gate insulating layer 13, an interlayer insulating layer 15, and a planarization layer 17. The pixel circuit PC may include a thin-film transistor TFT and a storage capacitor Cst.

A thin-film transistor TFT may be located on the buffer layer 11. The thin-film transistor TFT may include a first semiconductor layer A1, a first gate electrode G1, a first source electrode S1, and a first drain electrode D1. The thin-film transistor TFT may be connected to an organic light-emitting diode OLED to drive the organic light-emitting diode OLED.

The first semiconductor layer A1 may be located on the buffer layer 11 and may include polycrystalline silicon. According to some embodiments, the first semiconductor layer A1 may include amorphous silicon. According to some embodiments, the first semiconductor layer A1 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), or zinc (Zn). The first semiconductor layer A1 may include a channel region, a source region, and a drain region, the source region and the drain region being doped with impurities.

The first gate insulating layer 12 may be arranged to cover the first semiconductor layer A1. The first gate insulating layer 12 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The first gate insulating layer 12 may include a single layer or a multi-layer including the inorganic insulating material.

The first gate electrode G1 is located on the first gate insulating layer 12 to overlap the first semiconductor layer A1. The first gate electrode G1 may include at least one of molybdenum (Mo), aluminum (Al), copper (Cu), titanium (Ti) and/or the like and include a single layer or a multi-layer. As an example, the first gate electrode G1 may include a single Mo layer.

The second gate insulating layer 13 may cover the first gate electrode G1. The second gate insulating layer 13 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The second gate insulating layer 13 may include a single layer or a multi-layer including the inorganic insulating material.

A first upper electrode CE2 of a storage capacitor Cst may be located on the second gate insulating layer 13.

The first upper electrode CE2 may overlap the first gate electrode G1 located therebelow in the display area DA. The first gate electrode G1 and the first upper electrode CE2 overlapping each other with the second gate insulating layer 13 therebetween may constitute the storage capacitor Cst. The first gate electrode G1 may serve as a first lower electrode CE1 of the storage capacitor Cst.

The first upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 15 may be formed to cover the first upper electrode CE2. The interlayer insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The interlayer insulating layer 15 may include a single layer or a multi-layer including the inorganic insulating material.

The first source electrode S1 and the first drain electrode D1 are located on the interlayer insulating layer 15. The first source electrode S1 and the first drain electrode D1 may each include a conductive material including molybdenum (Mo), aluminum (Al), copper (Cu), and titanium (Ti) and include a single layer or a multi-layer including the above materials. As an example, the first source electrode S1 and the first drain electrode D1 may have a multi-layered structure of Ti/Al/Ti.

The planarization layer 17 may be arranged to cover the first source electrode S1 and the first drain electrode D1. The planarization layer 17 may have a flat upper surface such that a pixel electrode 21 located thereon is formed flat.

The planarization layer 17 may include an organic material or an inorganic material, and include a single-layered structure or a multi-layered structure. The planarization layer 17 may include a general-purpose polymer such as benzocyclobutene (BCB), polyimide, hexamethyldisiloxane (HMDSO), polymethylmethacrylate (PMMA) or polystyrene, polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer. The planarization layer 17 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). While the planarization insulating layer 17 is formed, to provide a flat upper surface after the layer is formed, chemical mechanical polishing may be performed on the upper surface of the layer.

The planarization layer 17 may have a via hole that exposes one of the first source electrode S1 and the first drain electrode D1 of the thin-film transistor TFT. The pixel electrode 21 may be electrically connected to the thin-film transistor TFT by being in contact with the first source electrode S1 or the first drain electrode D1 through the via hole.

The pixel electrode 21 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. As an example, the pixel electrode 21 may have a structure including layers on/under the reflective layer, the layers including ITO, IZO, ZnO, or In₂O₃. In this case, the pixel electrode 21 may have a stack structure of ITO/Ag/ITO.

A pixel-defining layer 19 may cover the edges of the pixel electrode 21 on the planarization layer 17 and may have a first opening OP1 that exposes the central portion of the pixel electrode 21. An emission area of the organic light-emitting diode OLED, that is, the size and shape of a sub-pixel Pm are defined by the first opening OP1.

The pixel-defining layer 19 may prevent or reduce arcs and the like from occurring at the edges of the pixel electrode 21 by increasing a distance between the edges of the pixel electrode 21 and an opposite electrode 23 over the pixel electrode 21. The pixel-defining layer 19 may include an organic insulating material such as polyamide, an acryl resin, benzocyclobutene, and hexamethyldisiloxane (HMDSO), and be formed by spin coating and the like.

An emission layer 22b is located in the first opening OP1 of the pixel-defining layer 19, wherein the emission layer 22b corresponds to the pixel electrode 21. The emission layer 22b may include a polymer material or a low-molecular weight material and be configured to emit red, green, blue, or white light.

An organic functional layer 22e may be located on and/or under the emission layer 22b. The organic functional layer 22e may include a first functional layer 22a and/or a second functional layer 22c. The first functional layer 22a or the second functional layer 22c may be omitted.

The first functional layer 22a may be located under the emission layer 22b. The first functional layer 22a may include a single layer or a multi-layer including an organic material. The first functional layer 22a may be a hole transport layer (HTL) having a single-layered structure. Alternatively, the first functional layer 22a may include a hole injection layer (HIL) and an HTL. The first functional layer 22a may be integrally formed to correspond to organic light-emitting diodes OLED and OLED′ included in the display area DA and a component area CA.

The second functional layer 22c may be located on the emission layer 22b. The second functional layer 22c may include a single layer or a multi-layer including an organic material. The second functional layer 22c may include an electron transport layer (ETL) and/or an electron injection layer (EIL). The second functional layer 22c may be integrally formed to correspond to the organic light-emitting diodes OLED included in the display area DA.

The opposite electrode 23 may be located on the second functional layer 22c. The opposite electrode 23 may include a conductive material having a low work function. As an example, the opposite electrode 23 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the opposite electrode 23 may further include a layer on the (semi) transparent layer, the layer including ITO, IZO, ZnO, or In₂O₃. The opposite electrode 23 may be integrally formed to correspond to the organic light-emitting diodes OLED included in the display area DA.

Layers from the pixel electrode 21 to the opposite electrode 23 formed in the display area DA may constitute the organic light-emitting diode OLED.

An upper layer 25 including an organic material may be formed on the opposite electrode 23. The upper layer 25 may be a layer for protecting the opposite electrode 23 and simultaneously or concurrently increasing a light-extracting efficiency. The upper layer 25 may include an organic material having a higher refractive index than that of the opposite electrode 23. Alternatively, the upper layer 25 may include layers of different refractive indexes that are stacked. As an example, the upper layer 25 may include a high refractive index layer/a low refractive index layer/a high refractive index layer that are stacked. In this case, the refractive index of the high refractive index layer may be 1.7 or more, and the refractive index of the low refractive index layer may be 1.3 or less.

The upper layer 25 may additionally include lithium fluoride (LiF). Alternatively, the upper layer 25 may additionally include an inorganic insulating material such as silicon oxide (SiO₂) and silicon nitride (SiNₓ). The upper layer 25 may be omitted when needed. However, for convenience of description, the case where the upper layer 25 is located on the opposite electrode 23 is mainly described below in detail.

The thin-film encapsulation layer 30 may be arranged to be in direct contact with the upper layer 25. In this case, the thin-film encapsulation layer 30 may be configured to prevent or reduce penetration of external moisture and oxygen by covering the display area DA and the peripheral area PA. The thin-film encapsulation layer 30 may include at least one organic encapsulation layer and at least one inorganic encapsulation layer. Hereinafter, for convenience of description, the case where the thin-film encapsulation layer 30 includes a first inorganic encapsulation layer 31, an organic encapsulation layer 32, a second inorganic encapsulation layer 33 that are sequentially stacked on the upper layer 25 is mainly described in detail.

In this case, the first inorganic encapsulation layer 31 may cover the opposite electrode 23 and may include silicon oxide, silicon nitride, and/or silicon oxynitride. Because the first inorganic encapsulation layer 31 is formed along a structure thereunder, the upper surface of the first inorganic encapsulation layer 31 is not flat. The organic encapsulation layer 32 may cover the first inorganic encapsulation layer 31 and, unlike the first inorganic encapsulation layer 31, the upper surface of the organic encapsulation layer 32 may be approximately flat. For example, the upper surface of a portion of the organic encapsulation layer 32 that corresponds to the display area DA may be approximately flat. The organic encapsulation layer 32 may include at least one material among polyethylene terephthalate, polyethylene naphthalate, polycarbonate, polyimide, polyethylene sulfonate, polyoxymethylene, and polyarylate, hexamethyldisiloxane. The second inorganic encapsulation layer 33 may cover the organic encapsulation layer 32 and may include silicon oxide, silicon nitride, and/or silicon oxynitride.

The touch sensor layer may be located on the thin-film encapsulation layer 30.

The protective film 92 including a protective film base 92a and an adhesive layer 92b may be located under the lower side of the substrate 10.

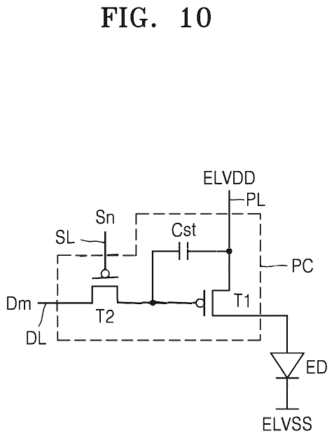

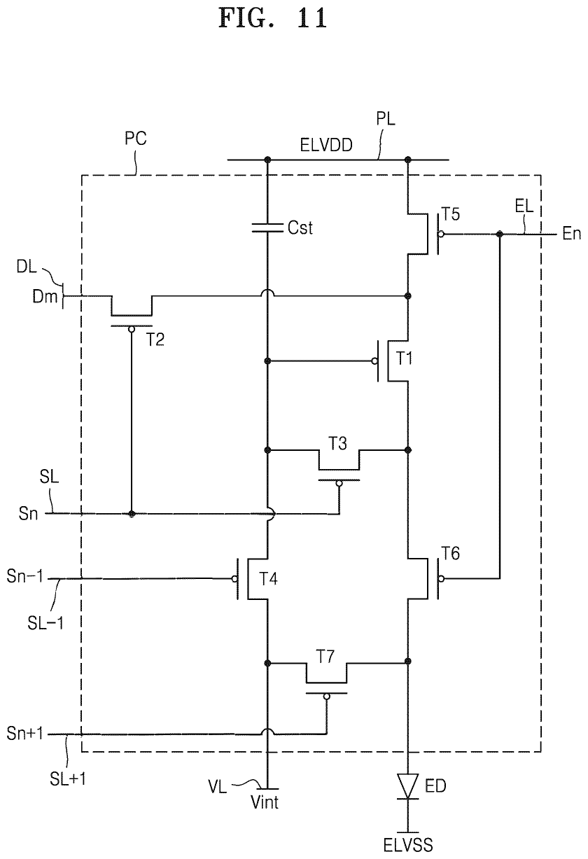

FIGS. 10 and 11 are schematic circuit diagrams of a circuit of the display panel shown in FIG. 9.

Referring to FIGS. 10 and 11, the pixel circuit PC may be connected to a light-emitting element ED to implement light emission of sub-pixels. The pixel circuit PC includes a driving thin-film transistor T1, a switching thin-film transistor T2, and a storage capacitor Cst. The switching thin-film transistor T2 is connected to a scan line SL and a data line DL, and configured to transfer a data signal Dm to the driving thin-film transistor T1 according to a scan signal Sn, wherein the data signal Dm is input through the data line DL, and the scan signal Sn is input through the scan line SL.

The storage capacitor Cst may be connected to the switching thin-film transistor T2 and a driving voltage line PL and configured to store a voltage corresponding to a difference between a voltage transferred from the switching thin-film transistor T2 and a driving voltage ELVDD supplied to the driving voltage line PL.

The driving thin-film transistor T1 may be connected to the driving voltage line PL and the storage capacitor Cst and configured to control a driving current according to the voltage stored in the storage capacitor Cst, the driving current flowing from the driving voltage line PL to the light-emitting element ED. The light-emitting element ED may be configured to emit light having a preset brightness corresponding to the driving current.

Although it is described with reference to FIG. 10 that the pixel circuit PC includes two thin-film transistors and one storage capacitor, the disclosure is not limited thereto.

Referring to FIG. 11, the pixel circuit PC may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 11 shows the case where each pixel circuit PC includes signal lines SL, SL−1, SL+1, EL, and DL, an initialization voltage line VL, and the driving voltage line PL, the disclosure is not limited thereto. According to some embodiments, at least one of the signal lines SL, SL−1, SL+1, EL, or DL, and/or the initialization voltage line VL may be shared by adjacent pixel circuits.

A drain electrode of the driving thin-film transistor T1 may be electrically connected to the light-emitting element ED through the emission control thin-film transistor T6. The driving thin-film transistor T1 may be configured to receive a data signal Dm and supply the driving current to the light-emitting element ED according to a switching operation of the switching thin-film transistor T2.

A gate electrode of the switching thin-film transistor T2 is connected to the scan line SL, and a source electrode is connected to the data line DL. A drain electrode of the switching thin-film transistor T2 may be connected to the source electrode of the driving thin-film transistor T1, and connected to the driving voltage line PL through the operation control thin-film transistor T5.

The switching thin-film transistor T2 is turned on according to a scan signal Sn transferred through the scan line SL and performs a switching operation of transferring a data signal Dm to a source electrode of the driving thin-film transistor T1, wherein the data signal Dm is transferred to the data line DL.

A gate electrode of the compensation thin-film transistor T3 may be connected to the scan line SL. A source electrode of the compensation thin-film transistor T3 is connected to a drain electrode of the driving thin-film transistor T1 and connected to a pixel electrode of the light-emitting element ED through the emission control thin-film transistor T6. A drain electrode of the compensation thin-film transistor T3 may be connected to one of electrodes of the storage capacitor Cst, a source electrode of the first initialization thin-film transistor T4, and the gate electrode of the driving thin-film transistor T1 together. The compensation thin-film transistor T3 is turned on according to a scan signal Sn received through the scan line SL and diode-connect the driving thin-film transistor T1 by connecting the gate electrode and the drain electrode of the driving thin-film transistor T1 to each other.

A gate electrode of the first initialization transistor T4 may be connected to a previous scan line SL−1. A drain electrode of the first initialization transistor T4 may be connected to the initialization voltage line VL. A source electrode of the first initialization thin-film transistor T4 may be connected to one of the electrodes of the storage capacitor Cst, a drain electrode of the compensation thin-film transistor T3, and the gate electrode of the driving thin-film transistor T1 together. That is, the first initialization thin-film transistor T4 may be turned on according to a previous scan signal Sn−1 received through the previous scan line SL−1 and may perform an initialization operation of initializing the voltage of the gate electrode of the driving thin-film transistor T1 by transferring an initialization voltage Vint to the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 is connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. The operation control thin-film transistor T5 and the emission control thin-film transistor T6 may be simultaneously (or concurrently) turned on according to an emission control signal En transferred through the emission control line EL, the driving voltage ELVDD is transferred to the light-emitting element ED, and the driving current flows through the light-emitting element ED.

A gate electrode of the second initialization thin-film transistor T7 may be connected to the next scan line SL+1. A source electrode of the second initialization thin-film transistor T7 may be connected to the pixel electrode of the light-emitting element ED. A drain electrode of the second initialization transistor T7 may be connected to the initialization voltage line VL. The second initialization thin-film transistor T7 may be turned on according to a next scan signal Sn+1 transferred through the next scan line SL+1 to initialize the pixel electrode of the light-emitting element ED.

Although it is shown in FIG. 11 that the first initialization thin-film transistor T4 and the second initialization thin-film transistor T7 are respectively connected to the previous scan line SL−1 and the next scan line SL+1, the disclosure is not limited thereto. According to some embodiments, both the first initialization thin-film transistor T4 and the second initialization thin-film transistor T7 may be connected to the previous scan line SL−1 and thus driven according to a previous scan signal Sn−1.

Another electrode of the storage capacitor Cst may be connected to the driving voltage line PL. One of the electrodes of the storage capacitor Cst may be connected to the gate electrode of the driving thin-film transistor T1, the drain electrode of the compensation thin-film transistor T3, and the source electrode of the first initialization thin-film transistor T4 together.

An opposite electrode (e.g., a cathode) of the light-emitting element ED is configured to receive a common voltage ELVSS. The light-emitting element ED may be configured to emit light by receiving the driving current from the driving thin-film transistor T1.

The pixel circuit PC is not limited to the number of thin-film transistors, the number of storage capacitors, and the circuit design described with reference to FIGS. 10 and 11, and the number of thin-film transistors, the number of storage capacitors, and the circuit design may be variously changed.

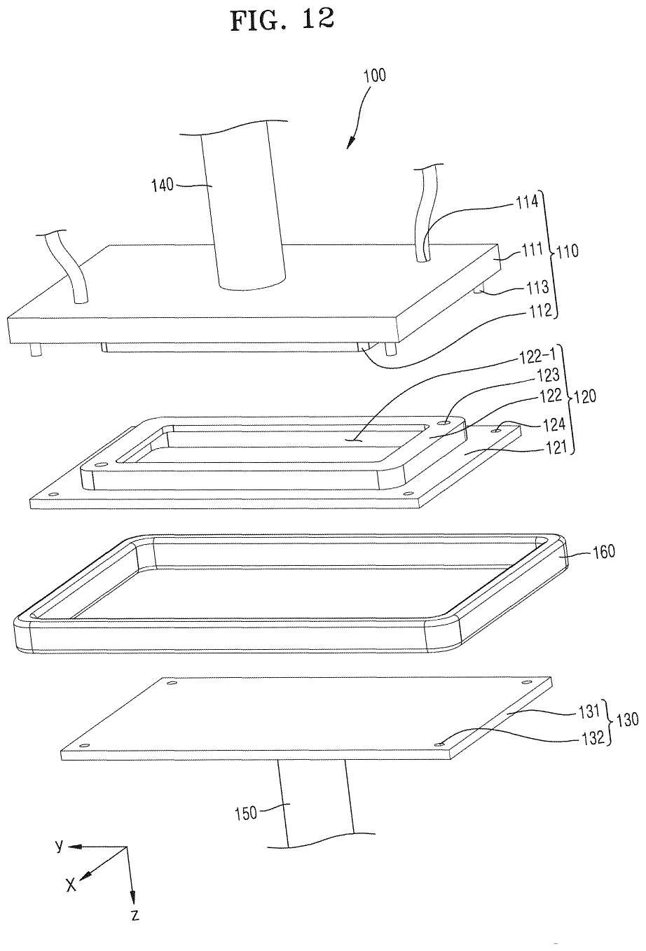

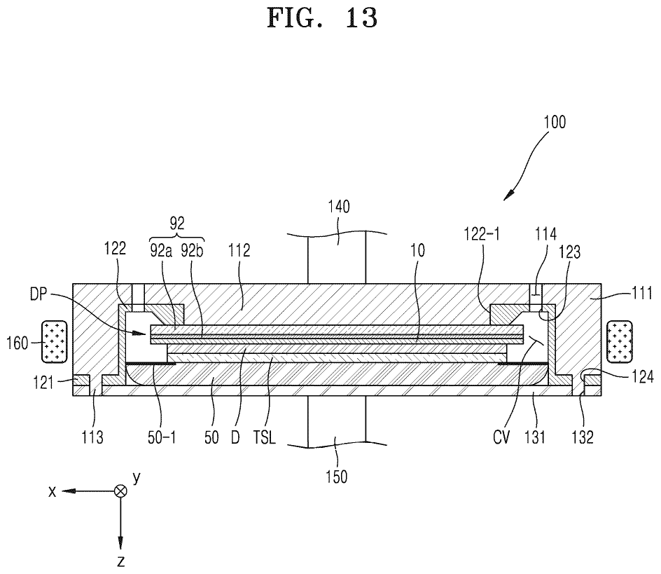

FIG. 12 is a schematic perspective view of an apparatus for manufacturing a display apparatus according to some embodiments. FIG. 13 is a schematic cross-sectional view of the apparatus 100 for manufacturing a display apparatus shown in FIG. 12.

Referring to FIGS. 12 and 13, the apparatus 100 for manufacturing a display apparatus may include a first jig 110, a mold 120, a second jig 130, a driver, and a light source part 160.

The first jig 110 may include a first jig body 111, a pressurizer 112, a coupler 113, and a first injector 114. The pressurizer 112 may protrude from the first jig body 111. The pressurizer 112 may be configured to apply force to a portion of the display panel DP by being in contact with the portion of the display panel DP. The coupler 113 may protrude from the first jig body 111. In this case, the coupler 113 may be formed in a pin shape and may protrude from the first jig body 111. In this case, the coupler 113 may be provided in plurality, and the plurality of couplers 113 may be arranged to be spaced apart from each other at the edge portions of the first jig body 111. The first injector 114 may be located on the first jig body 111. In this case, at least one first injector 114 may be provided, and in the case where a plurality of first injectors 114 are provided. In the case where the plurality of injectors 114 are provided, the plurality of injectors 114 may be arranged to be spaced apart from each other. The first injector 114 may be connected to a separate supply part and a pipe configured to supply photocurable resin from the outside, or a nozzle configured to spray photocurable resin may be inserted to the first injector 114.

The mold 120 may move together with the first jig 110 or be coupled to the first jig 110. The mold 120 may include a mold body 121, a mold protrusion 122, a second injector 123, and a first receiver 124. The mold body 121 may have a plate shape and be in selective contact with the second jig 130 by being in close contact with the second jig 130. The mold protrusion 122 may protrude from the mold body 121 toward the first jig 110. The mold protrusion 122 may include an opening area 122-1. The pressurizer 112 may be inserted into the opening area 122-1. In this case, the pressurizer 112 may pass through the opening area 122-1 and be in contact with the display panel DP, for example, the backside of the display panel DP. The second injector 123 may be arranged to correspond to the first injector 114. The second injector 123 may be located on the mold protrusion 122. The first receiver 124 may be arranged to correspond to the coupler 113. In this case, the first receiver 124 may be formed in a hole shape.

The second jig 130 may include a second jig body 131 having a plate shape, and a second receiver 132 into which the coupler 113 is inserted. The second receiver 132 may be located in the second jig 131 to correspond to the coupler 113 and the first receiver 124. In this case, a portion of the coupler 113 protruding to pass through the first receiver 124 may be inserted into the second receiver 132.

The driver may be connected to at least one of the first jig 110 or the second jig 130 to linearly move the at least one of the first jig 110 or the second jig 130. As an example, the driver may be connected to the first jig 110 to bring the first jig 110 to the second jig 130 or separate the first jig 110 from the second jig 130. According to some embodiments, the driver may be connected to the second jig 130 to bring the second jig 130 to the first jig 110 or separate the second jig 130 from the first jig 110. According to some embodiments, the driver may include a first driver 140 connected to the first jig 110, and a second driver 150 connected to the second jig 130. Hereinafter, for convenience of description, the case where the driver includes the first driver 140 and the second driver 150 is mainly described in detail.

The driver may be formed in various forms. As an example, the driver may include a cylinder. According to some embodiments, the driver may include a linear motor. According to some embodiments, the driver may include a motor and a ball screw connected to the motor. In this case, the driver is not limited thereto and may include all devices and all structures connected to at least one of the first jig 110 or the second jig 130 and move the at least one of the first jig 110 or the second jig 130.

The light source part 160 may be located on the lateral surface of the display panel DP to irradiate light toward the display panel DP. In this case, the light source part 160 may be configured to emit visible light to the outside, and particularly, supply light of a wavelength in the range with a peak top of 450 nm to 500 nm (or about 450 nm to about 500 nm). The light source part 160 may have various forms. As an example, the light source part 160 may have a form of a point light source. According to some embodiments, the light source part 160 may be located on a portion of the lateral surface of the display panel DP and be formed in a linear form. The light source part 160 may be arranged to surround the entire lateral surface of the display panel DP.

In operation of the apparatus 100 for manufacturing the display apparatus, the display panel DP may be located on the second jig 130, and then, the first jig 110 and the mold 120 may be located on the display panel DP. In this case, at least one of the first driver 140 or the second driver 150 may be configured to arranged the first jig 110 and the second jig 130 such that the first jig 110 and the second jig 130 are apart from each other. In addition, the mold 120 may be coupled to the first jig 110, or only the mold 120 may be separately located on the display panel DP. In this case, the mold 120 and the second jig 130 may be arranged such that the first receiver 124 and the second receiver 132 correspond to each other.

At least one of the first driver 140 or the second driver 150 may operate to bring the first jig 110 and the second jig 130 closer to each other. In this case, the first jig 110 may be in close contact with the second jig 130. The mold protrusion 122 may be inserted to the opening area 122-1 to be in contact with the display panel DP and be configured to prevent or reduce instances of the display panel DP moving by applying force to the display panel DP. In addition, because the coupler 113 is inserted into the first receiver 124 and the second receiver 132, the coupler 113 may be configured to prevent or reduce instances of the mold 120 moving and prevent or reduce instances of the first jig 110 and the second jig 130 moving relative to each other.

Photocurable resin may be injected into the space CV through the first injector 114 and the second injector 123 in communicate with the space CV. Photocurable resin may be injected into the space CV through the first injector 114 and the second injector 123 in communicate with the space CV. Then, the light source part 160 may be configured to irradiate light through the entire lateral surfaces of the first jig 110 and the second jig 130 to cure the photocurable resin. In this case, each of the first jig 110 and the mold 120 may include a transparent material. As an example, the first jig 110 may include at least one of transparent materials such as polymethyl methacrylate (PMMA), polycarbonate (PC), glass, or quartz. In addition, the mold 120 is flexible to some extent and may include at least one of transparent silicon rubber, plastic rubber, or Teflon rubber.

When the curing of the photocurable resin is completed by irradiating light, at least one of the first driver 140 or the second driver 150 may be operated to separate the first jig 110 and the second jig 130 from each other. In this case, the mold 120 may move with the first jig 110 and be separated from the second jig 130, or the first jig 110 may be separated from the mold 120 and then the mold 120 may be separately removed.

Although the coupler 113 is provided to the first jig 110 in the above description, the embodiments are not limited thereto. According to some embodiments, the coupler 113 may be located on the second jig 130, and the second receiver 132 may be located in the first jig 110. According to some embodiments, the coupler 113 may be located on the mold 120, the first receiver 124 may be located in the first jig 110, and the second receiver 132 may be located in the second jig 130. In this case, the coupler 113 of the mold 120 may include a first coupler protruding toward the first jig 110, and a second coupler protruding toward the second jig 130.

Hereinafter, a method of forming a first protective layer and a second protective layer is described in more detail.

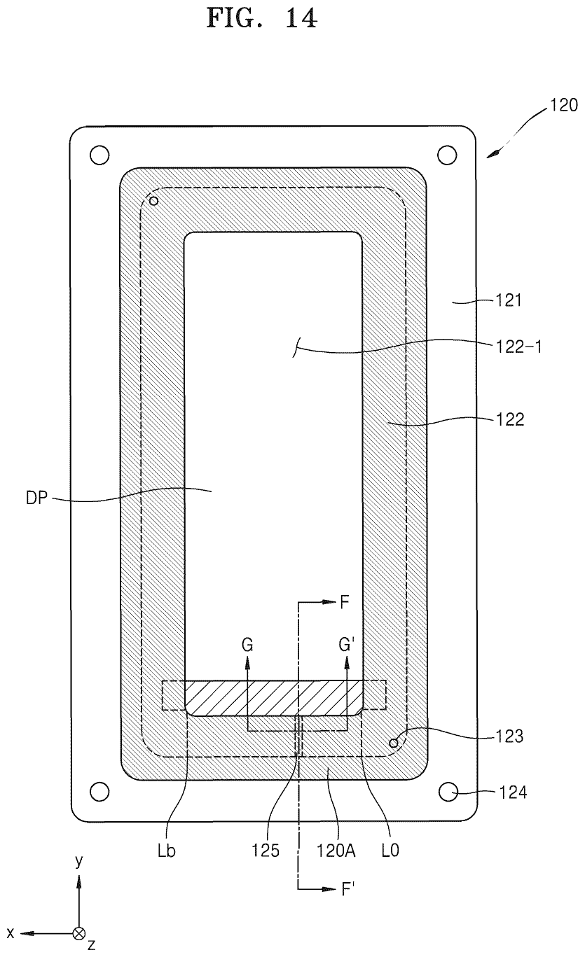

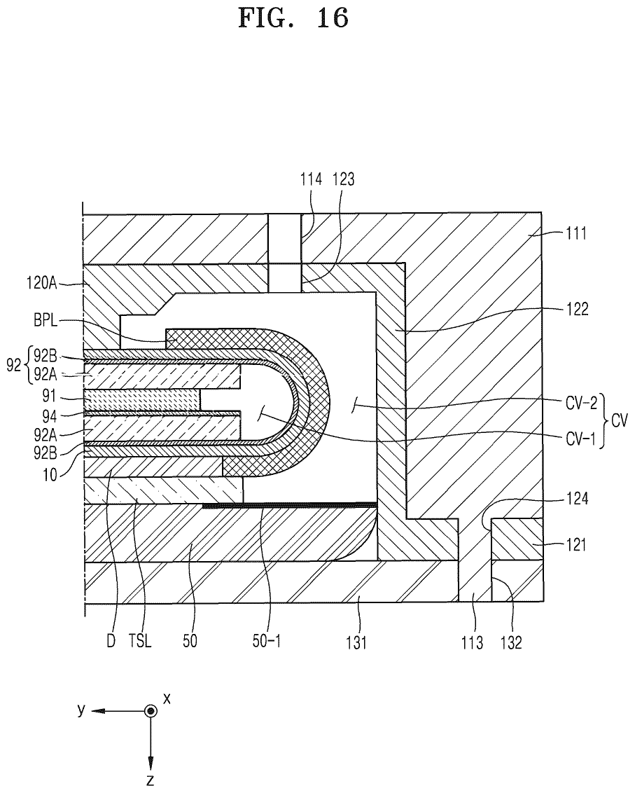

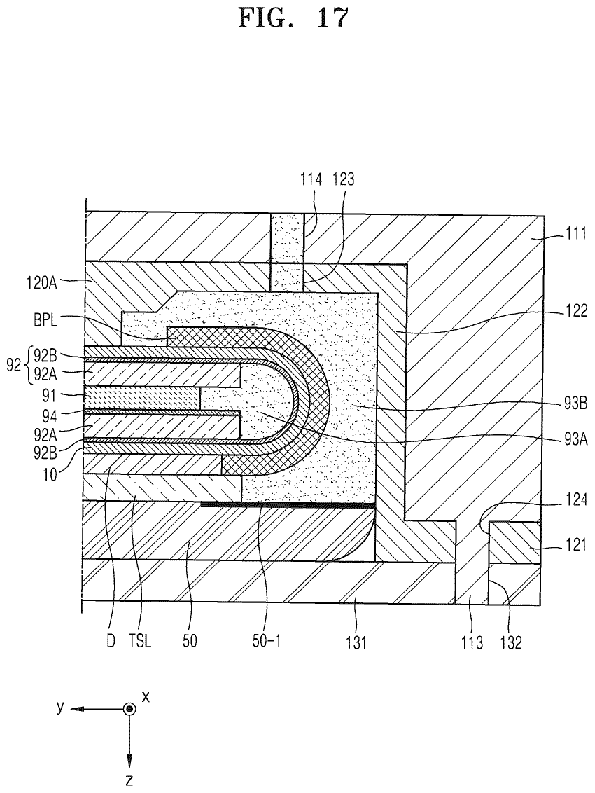

FIGS. 14 to 17 are schematic cross-sectional views showing an apparatus and a method of manufacturing a display apparatus according to some embodiments. For example, FIG. 14 is a schematic plan view of the apparatus for manufacturing the display apparatus according to some embodiments, and the first jig 110 is omitted.

Referring to FIGS. 14 to 17, the mold 120 may be arranged to surround the periphery, that is, the edges of the display panel DP. The mold 120 may form the space CV in the periphery, that is, the edges of the display panel DP. Hereinafter, to mainly describe the forming of the first protective layer 93A and the second protective layer 93B, one edge (the edge in a −y direction of FIG. 14) of the mold 120 in which the bending area BA is arranged is mainly described. In this case, the edge of the mold 120 in which the bending area BA is arranged may be defined as a first mold portion 120A. That is, the first mold portion 120A may extend in the first direction (the x direction) and may be a portion of the mold 120 surrounding the bending area BA and a portion of the pad area PDA. The space CV formed by the first mold portion 120A may include a first space CV1 and a second space CV2, wherein the first space CV1 is an inner space of the bending area BA with respect to the bending area BA, and the second space CV2 is an outer space of the bending area BA with respect to the bending area BA.

The display panel that has bent in the bending area BA is prepared, and then, the first jig 110, the mold 120, and the second jig 130 are coupled as describe above, and then photocurable resin may be injected into the space CV. In this case, according to some embodiments, the first injector 114 and the second injector 123 through which the photocurable resin is injected may be arranged at one of the first mold portion 120A, for example, the right end of FIG. 14. The photocurable resin may be injected through the first injector 114 of the first jig 110 and the second injector 123 of the mold 120, and a portion of the injected photocurable resin may flow from the right end of the first mold portion 120A toward the left end and enter the inside of the second space CV2 between the first mold portion 120A and the outer surface of the bending area BA. In addition, another portion of the injected photocurable resin may flow from the right end of the first mold portion 120A toward the left end and enter the inside of the first space CV1 formed by the bent inner surface of the bending area BA, the protective film 92, and the cushion layer 91. That is, the injected photocurable resin may be branched from the right end of the bending area BA to flow to the first space CV1 and the second space CV2.

Then, the light source 160 may be configured to irradiate light to the lateral surface of the display panel DP from the outside of the first jig 110 and the mold 120. The light may cure the photocurable resin located in the second space CV2. Light irradiated to the bending area of the display panel may cure not only the photocurable resin of the second space CV located outside the bending area but also the photocurable resin located in the first space CV1. Particularly, in this case, due to bending area BA located between the first space CV1 and the second space DV2, light may pass through the bending area BA with almost no blocking and be transferred to the photocurable resin inside the first space CV1.

In this case, the photocurable resin located in the first space CV1 may form the first protective layer 93A, and the photocurable resin located in the second space CV2 may form the second protective layer 93B. Particularly, the second protective layer 93B may be located on the edge of the display panel DP and the bending protective layer BPL. In addition, the second protective layer 93B may be integrally formed with the first protective layer 93A by being connected to the first protective layer 93A. The first protective layer 93A and the second protective layer 93B may be connected to each other.

Accordingly, the apparatus for manufacturing the display apparatus and the method of manufacturing the display apparatus may be configured to form the protective layer in the first space CV1 and the second space CV2, simultaneously (or concurrently). In addition, because the apparatus for manufacturing the display apparatus and the method of manufacturing the display apparatus are configured to form the protective layer using light, time taken to form the protective layer may be reduced. Because the apparatus for manufacturing the display apparatus and the method of manufacturing the display apparatus do not need to apply excessive energy when forming the protective layer, damage to various elements of the display panel when forming the protective layer may be reduced. In addition, because the bracket may be attached to the protective layer, a separate region of the display panel DP for attaching the bracket is not required. Accordingly, the region of the display panel DP provided to attach the bracket may not be provided, and a dead space may be reduced.

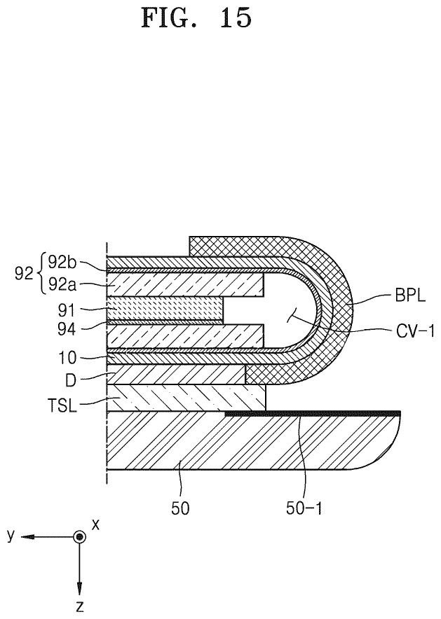

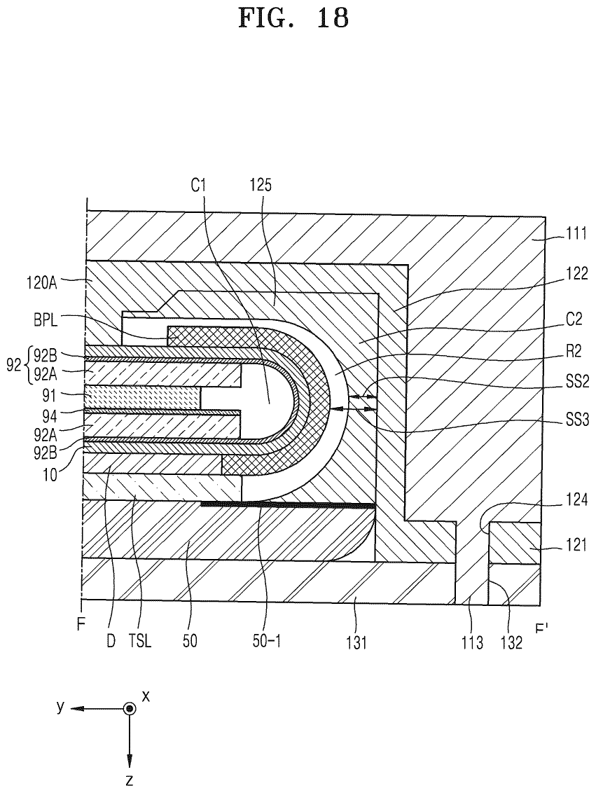

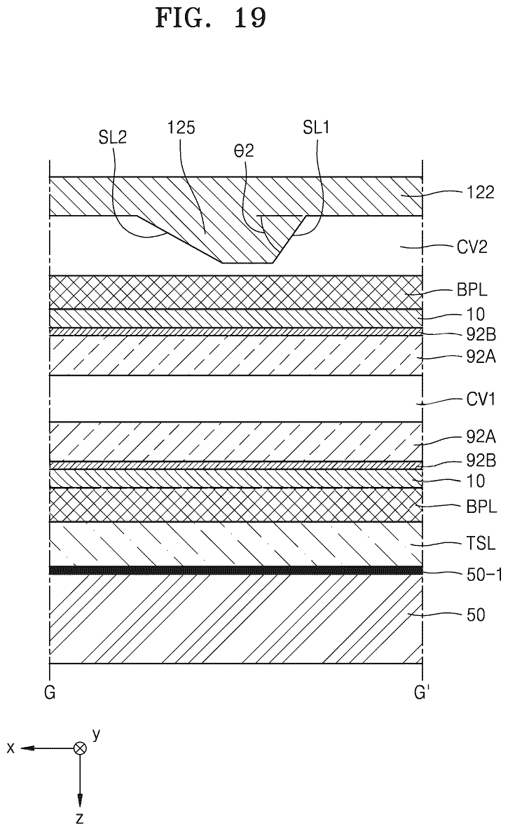

FIG. 18 is a schematic cross-sectional view of an apparatus for manufacturing a display apparatus according to some embodiments, taken along the line F-F′ of FIG. 14. FIG. 19 is a schematic cross-sectional view of an apparatus for manufacturing a display apparatus according to some embodiments, taken along the line G-G′ of FIG. 14. FIGS. 18 and 19 mainly show a portion of the first mold portion 120A in which a blocking portion 125 is located. FIGS. 15 to 17 may be understood as description of a portion of the first mold portion 120A in which the blocking portion 125 is not located.

Referring to FIGS. 18 and 19, the first mold portion 120A may include the blocking portion 125. In the backside view of FIG. 14, the blocking portion 125 may be located in the width of bending area BA received in the inner space of the first mold portion 120A, for example, the length of the bending area BA in the first direction (the x direction). According to some embodiments, the blocking portion 125 may be located between one end of the width of the bending area BA, for example, a first end, which is a right end in FIG. 14, and the center of the width of the bending area BA. In other words, when the location of the first end, which is the right end of the bending area BA, is defined as L0 and the location of the second end, which is the left end, is defined as Lb, the blocking portion 125 may be located between L0 and Lb. In addition, the blocking portion 125 may be located between L0 and 0.75 Lb, or located between L0 and 0.5 Lb. In addition, the blocking portion 125 may be located between one end, for example, the right end of the first mold portion 120A and the center of the length in the first direction of the first mold portion 120A.

The blocking portion 125 may protrude from the first mold portion 120A, for example, the inner surface of the mold protrusion 122 to the bending area BA and the pad area PDA received in the inner space of the first mold portion 120A. In other words, the blocking portion 125 may be arranged outside the bending area BA and the pad area PDA. In this case, the blocking portion 125 may be spaced apart by a preset interval from the outer surface of the bending area BA and the pad area PDA. According to some embodiments, a protrusion length SS2 of the blocking portion 125 that protrudes from the inner surface of the first mold portion 120A may be in a range of 70% to 85% (or about 70% to about 85%) of a length SS3 from the inner surface of the first mold portion 120A to the outer surface of the bending area BA.

In addition, referring to FIG. 18, when viewed in the first direction (e.g., the x direction), the cross-section of the blocking portion 125 may have a shape that protrudes in an approximately ‘¬’ shape.

Referring to FIG. 19, when viewed in the second direction (e.g., the y direction), the cross-section of the blocking portion 125 may be formed to increasingly protrude toward the center of the blocking portion 125. According to some embodiments, when viewed in the second direction, the cross-section of the blocking portion 125 may include a first inclined surface SL1 and a second inclined surface SL2, wherein the first inclined surface SL1 is located on one side in the first direction (e.g., the x direction) from the center of the blocking portion 125 and inclined, and the second inclined surface SL2 is located on the other side in the first direction from the center of the blocking portion 125 and inclined. The first inclined surface SL1 may be located on a side adjacent to the first injector 114 and the second injector 123 located on one end of the first mold portion 120A with respect to the center of the blocking portion 125, and the second inclined surface SL2 may be located on the opposite side thereof with respect to the center of the blocking portion 125. According to some embodiments, the slope of the first inclined surface SL1 may be greater than the slope of the second inclined surface SL2. In this case, the slopes and the slope angles of the first inclined surface SL1 and the second inclined surface SL2 may denote angles inclined from the plane of the inner surface of the first mold portion 120A. In addition, according to some embodiments, a slope angle θ2 of the first inclined surface SL1 may be in a range of 50° to 70° (or about 50° to about 70°). Because the slope of the first inclined surface SL1 is greater than the slope of the second inclined surface SL2, the protruding cross-section of the blocking portion 125 may be formed to protrude in approximately a half-streamline shape.

As described above, according to embodiments, the blocking portion 125 may be configured to reduce a flow pass of the second space CV2. As described above, the photocurable resin injected through the first injector 114 and the second injector 123 located on one end of the first mold portion 120A may reach the bending area BA, be branched from the bending area BA, may flow through the first space CV1 inside the bending area BA and the second space CV2 outside the bending area BA, and flow to the other end of the first mold portion 120A. In this case, because the area of the cross-sectional area of the first space CV1 is different from the cross-sectional area of the second space CV2, that is, the cross-sectional area of the first space CV1 is less than the cross-sectional area of the second space CV2, the photocurable resin flowing into the second space CV2 may reach a junction point before the photocurable resin flowing into the first space CV1. Due to this difference in the flowing velocity, the first space CV1 inside the bending area BA may not be completely filled with the photocurable resin and bubbles may be formed.

According to embodiments, because the cross-sectional area of the second space CV2 may be reduced by the blocking portion 125, the blocking portion 125 may serve as a gate and be configured to slow down the flow speed of the photocurable resin flowing into the second space CV2. When the cross-sectional area of the first space CV1 is defined as C1, the cross-sectional area of the second space CV2 is defined as C2, and the cross-sectional area of the second space CV2 after being narrowed by the blocking portion 125 is defined as R2, the following inequality may be established between the cross-sectional areas according to some embodiments. (0.1*C2)<R2<(0.7*C2), C1<R2

Accordingly, because the flow velocity of the photocurable resin flowing into the second space CV2 is adjusted by the blocking portion 125, the photocurable resin flowing into the first space CV1 and the photocurable resin flowing into the second space CV2 may simultaneously (or concurrently) reach the junction point. This may prevent or reduce instances of bubbles occurring in the first space CV1.

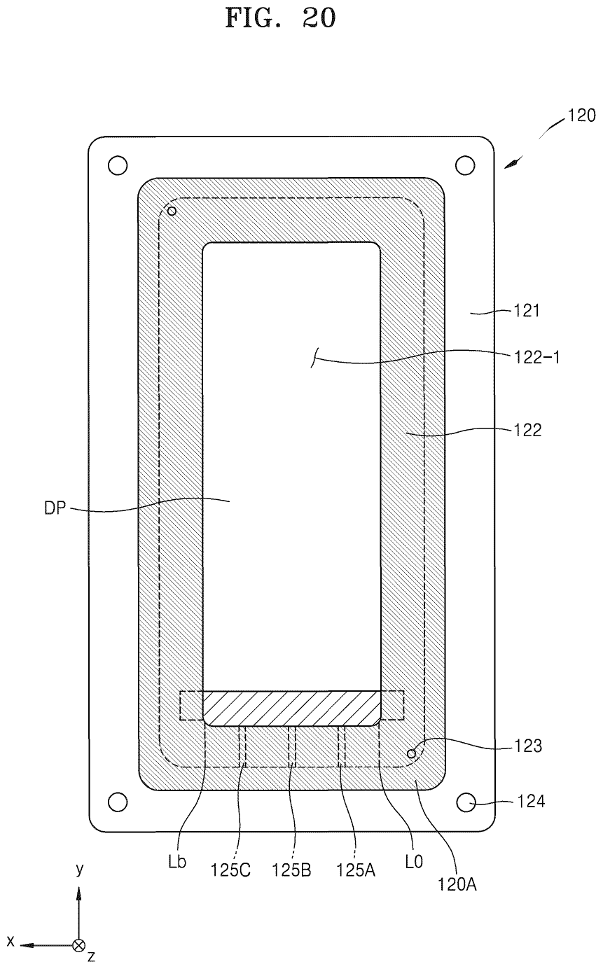

FIG. 20 is a schematic cross-sectional view of an apparatus for manufacturing a display apparatus according to some embodiments, and is similar to FIG. 14. Because the apparatus for manufacturing the display apparatus according to some embodiments is similar to the above-described apparatus for manufacturing the display apparatus, and some differences are mainly described below.

According to some embodiments, the blocking portions 125 may be provided in plurality. As an example, the blocking section 125 may be provided in two or three pieces. Hereinafter, as an example, the case where the blocking section 125 includes three pieces of a first blocking portion 125A, a second blocking portion 125B, and a third blocking portion 125C is mainly described.

The first blocking portion 125A, the second blocking portion 125B, and the third blocking portion 125C may be spaced apart from each other and sequentially arranged in the first direction (the x direction), which is an extension direction of the first mold portion 120A. Even in this case, as described above, the plurality of blocking portions 125 may be arranged inside the width of the bending area BA to overlap the bending area BA in the backside view. The first blocking portion 125A may be located on a side closer to the first injector 114 and the second injector 123. The third blocking portion 125C may be located on the opposite side thereof, and the second blocking portion 125B may be located between the first blocking portion 125A and the third blocking portion 125C.

In this case, according to some embodiments, the protrusion lengths of the plurality of blocking portions 125 that protrude from the inner surface of the first mold portion 120A may be different from each other. As an example, the protrusion length of the first blocking portion 125A may be greater than the protrusion length of the second blocking portion 125B, and the protrusion length the second blocking portion 125B may be greater than the protrusion length of the third blocking portion 125C. In this case, the velocity of the photocurable resin flowing into the second space CV2 may be more effectively adjusted. In addition, it would be understood that the protrusion lengths of the plurality of blocking portions 125 may be equal to each other.

According to some embodiments, the edge of the display panel may be protected and destruction of the bent portion of the display panel may be reduced.

In addition, because the protective layer is formed by using light to cure resin, the display apparatus may be manufactured conveniently and quickly.

In addition, because instances of bubbles being generated when forming the protective layer may be prevented or reduced, defects of the protective layer may be prevented or reduced.

The characteristics of embodiments according to the present disclosure are not limited to the above mentioned characteristics and other characteristics not mentioned may be more clearly understood by those of ordinary skill in the art from the following claims, and their equivalents.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising a display panel, the display panel comprising:
a substrate including a display area, a pad area, and a bending area,
wherein the display area and the pad area have a width in a first direction and a length in a second direction, and the bending area connects the display area to the pad area in the second direction and bends such that the display area faces the pad area;
a first protective layer inside the bending area of the substrate; and
a second protective layer on at least a portion of an edge of the substrate and outside the bending area,
wherein the second protective layer includes a groove concave toward an inner surface from an outer surface of the second protective layer.

2. The display apparatus of claim 1, wherein the groove is within a width in the first direction of the bending area.

3. The display apparatus of claim 2, wherein the groove is between one side end of the width in the first direction of the bending area and a center of the width.

4. The display apparatus of claim 1, wherein an inner surface of the groove is spaced apart in a thickness direction of the second protective layer from the bending area and an outer surface of the pad area.

5. The display apparatus of claim 4, wherein a depth of the groove is in a range of 70% to 85% of a thickness of the second protective layer.

6. The display apparatus of claim 4, wherein a cross-section of the groove viewed in a first direction has a ‘¬’ shape.

7. The display apparatus of claim 4, wherein, in a view from the second direction, a cross-section of the groove is concave and gets increasingly deeper toward a center thereof.

8. The display apparatus of claim 7, wherein, in a view from the second direction, the cross-section of the groove includes a first inner surface and a second inner surface, the first inner surface being on a first side in the first direction from the center of the groove and inclined, and the second inner surface being on a second side in the first direction and inclined.

9. The display apparatus of claim 8, wherein a slope of the first inner surface is greater than a slope of the second inner surface.

10. The display apparatus of claim 8, wherein a slope angle of the first inner surface is in a range of 50° to 70°.

11. The display apparatus of claim 1, wherein the first protective layer and the second protective layer include a photocurable resin.

12. An apparatus for manufacturing a display apparatus, the apparatus comprising:
a first jig;
a second jig on which a display panel is seated, the second jig facing the first jig; and
a mold between the first jig and the second jig, selectively coupled to the first jig, and forming a space in an edge portion of the display panel in cooperation with the second jig, wherein a resin is injected into the space,
wherein the display panel includes a bending area arranged in a portion of the edge portion to bend, and the mold includes a first mold portion including a first space in which the bending area is received and which is an inner space of the bending area, and a second space which is an outer space of the bending area, wherein the first mold portion includes a blocking portion protruding from an inner surface thereof toward the bending area.

13. The apparatus of claim 12, wherein, in a rear view, the blocking portion is arranged in a width of the bending area.

14. The apparatus of claim 12, wherein, in a rear view, the blocking portion is located between one side end of a width of the bending area and a center of the width.

15. The apparatus of claim 12, wherein a protrusion length of the blocking portion from the inner surface of the first mold portion is in a range of 70% to 85% of a length from the inner surface of the first mold portion to an outer surface of the bending area.

16. The apparatus of claim 12, wherein, in a view in a width direction of the bending area, a cross-section of the blocking portion has a ‘¬’ shape.

17. The apparatus of claim 12, wherein, in a view in a length direction of the bending area, a cross-section of the blocking portion protrudes more toward a center thereof.

18. The apparatus of claim 17, wherein, in a view in a length direction of the bending area, a cross-section of the blocking portion includes a first inclined surface arranged on a first side of a center of the blocking portion and inclined, and a second inclined surface arranged on a second side and inclined.

19. An electronic apparatus comprising:
a display panel; and
a bracket supporting the display panel,
the display panel comprising:
a substrate including a display area, a pad area, and a bending area,
wherein the display area and the pad area have a width in a first direction and a length in a second direction, and the bending area connects the display area to the pad area in the second direction and bends such that the display area faces the pad area;
a first protective layer inside the bending area of the substrate; and
a second protective layer on at least a portion of an edge of the substrate and outside the bending area,
wherein the second protective layer includes a groove concave toward an inner surface from an outer surface of the second protective layer.

20. The apparatus of claim 19, wherein the electronic apparatus further comprises a main circuit board, wherein a main circuit board comprises at least one of a main processor, a camera apparatus and a main connector.
